(19) United States
(12) Patent Application Publication
(10) Pub. No.: US 2026/0253199 A1
(43) Pub. Date: Aug. 27, 2026

(54) COMPUTER PROGRAM, INFORMATION PROCESSING METHOD, AND INFORMATION PROCESSING DEVICE

(71) Applicant: Tokyo Electron Limited, Tokyo (JP)

(72) Inventors: Takahiro NAKAMURA, Sapporo City (JP); Taisei KONDO, Sapporo City (JP); Shota YAMADA, Sapporo City (JP)

(73) Assignee: Tokyo Electron Limited, Tokyo (JP)

(21) Appl. No.: 19/651,860

(22) Filed: Apr. 20, 2026

Related U.S. Application Data
(63) Continuation of application No. PCT/JP2024/036373, filed on Oct. 11, 2024.

(30) Foreign Application Priority Data
Nov. 2, 2023 (JP) 2023-188788
May 7, 2024 (JP) 2024-075318

(51) Int. Cl. G06T 7/00; G06T 7/10; G06V 10/46; G06V 10/74; G06V 10/764

(52) U.S. Cl. CPC G06T 7/0006; G06T 7/001; G06T 7/10; G06V 10/46; G06V 10/761; G06V 10/764; G06T 2207/30148

(57) ABSTRACT

A non-transitory computer-readable medium storing executable instructions, which when executed by controller circuitry, cause the controller circuitry to perform a method of detection processing, related to patterns having a given shape formed on a substrate, on at least one captured image obtained by imaging the substrate, the method including: detecting an image region in which one of the patterns is captured from the captured image; detecting a contour of the pattern in the image region; detecting a length measurement location for the pattern based on a detection result of the contour; acquiring condition information including at least one of coordinate designation, region designation, or text as a detection condition in at least one type of detection processing of detection processing of the image region, the detection processing of the contour, and the detection processing of the length measurement location.

### CROSS-REFERENCE TO RELATED APPLICATIONS

This application is a bypass continuation application of International Application No. PCT/JP2024/036373 having an international filing date of Oct. 11, 2024 and designating the United States, the international application being based upon and claiming the benefit of priority from Japanese Patent Applications No. 2023-188788, filed on Nov. 2, 2023, and No. 2024-075318 filed on May 7, 2024, the entire contents of each of which are incorporated herein by reference.

### BACKGROUND

### Field

The present disclosure relates to a computer program, an information processing method, and an information processing device.

### Background Art

PTL 1 proposes a substrate processing device in which an inspection unit in which a film thickness measuring device, a line width measuring device, an overlay measuring device, and a macro defect inspection device are stacked and located is provided in the middle of a transfer path of a substrate, and in which a substrate to be processed can be selectively loaded into each inspection unit, so that the substrate can be inspected in the device as necessary.

### CITATION LIST

### Patent Documents

PTL 1: JP2002-151403A

### SUMMARY

The present disclosure provides a non-transitory computer-readable medium storing executable instructions, which when executed by controller circuitry, cause the controller circuitry to perform a method of detection processing, related to a plurality of patterns having a given shape formed on a substrate processed by a substrate processing device, on at least one captured image obtained by imaging the substrate, the method of detection processing including: detecting an image region in which one of the patterns is captured from the captured image; detecting a contour of the pattern in the image region; detecting a length measurement location for the pattern based on a detection result of the contour; acquiring condition information including at least one of coordinate designation, region designation, or text as a detection condition in at least one type of detection processing of detection processing of the image region, the detection processing of the contour, and the detection processing of the length measurement location; and performing the detection processing related to another pattern based on the acquired condition information related to the one pattern.

### BRIEF DESCRIPTION OF DRAWINGS

The scope of the present disclosure is best understood from the following detailed description of exemplary embodiments when read in conjunction with the accompanying drawings.

FIG. 1 is a schematic diagram illustrating an overview of an information processing system according to the present embodiment;

FIG. 2 is a schematic diagram illustrating a configuration example of a pattern formed on a substrate;

FIG. 3 is a schematic diagram illustrating an overview of detection processing performed by an information processing device according to the present embodiment;

FIG. 4 is a block diagram illustrating a configuration example of the information processing device according to the present embodiment;

FIG. 5 is a flowchart illustrating an example of a procedure of pattern detection processing performed by the information processing device according to the present embodiment;

FIG. 6 is a schematic diagram illustrating a configuration example of a contour detection model according to the present embodiment;

FIG. 7 is a schematic diagram illustrating an example of contour detection processing;

FIG. 8 is a schematic diagram illustrating a configuration example of a similar image contour detection model;

FIG. 9 is a schematic diagram illustrating an example of a training method of the similar image contour detection model;

FIG. 10 is a flowchart illustrating an example of a procedure of the contour detection processing performed by the information processing device according to the present embodiment;

FIG. 11 is a schematic diagram illustrating a configuration example of a length measurement location detection model based on text information;

FIG. 12 is a schematic diagram illustrating a configuration example of a similar image length measurement location detection model;

FIG. 13 is a schematic diagram illustrating an example of a training method of the similar image length measurement location detection model;

FIG. 14 is a flowchart illustrating an example of a procedure of length measurement location detection processing performed by the information processing device according to the present embodiment;

FIG. 15 is a flowchart illustrating an example of a procedure of state determination processing performed by the information processing device according to the present embodiment;

FIG. 16 is a flowchart illustrating an example of a procedure of contour detection processing performed by an information processing device according to a second embodiment;

FIG. 17 is a schematic diagram illustrating a method of adding information to a database;

FIG. 18 is a schematic diagram illustrating an example of a screen display by the information processing device according to the present embodiment;

FIG. 19 is a schematic diagram illustrating an example of a screen display by the information processing device according to the present embodiment;

FIG. 20 is a schematic diagram illustrating an example of a screen display by the information processing device according to the present embodiment; and

FIG. 21 is a schematic diagram illustrating an example of a screen display by the information processing device according to the present embodiment.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### First Embodiment

### <System Overview>

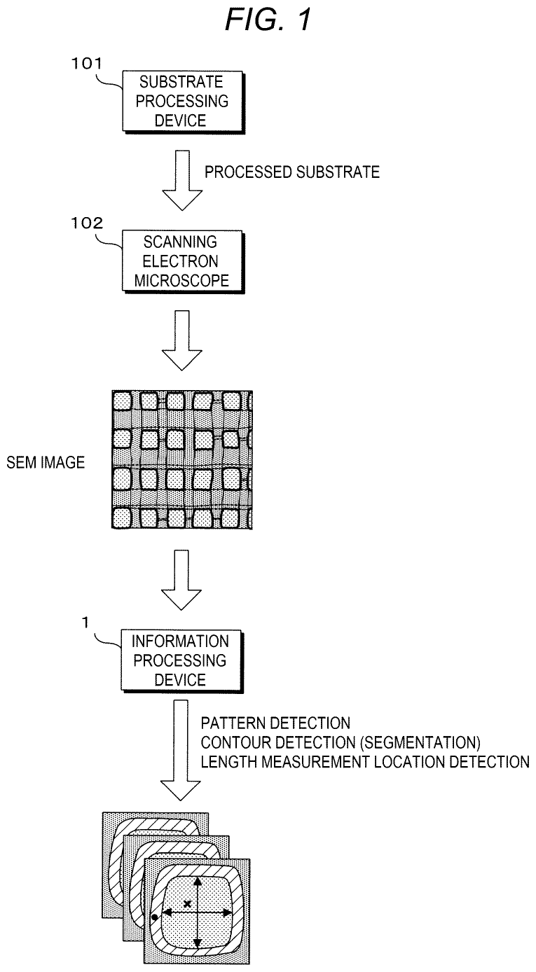

FIG. 1 is a schematic diagram illustrating an overview of an information processing system according to the present embodiment. The information processing system according to the present embodiment includes an information processing device 1, a substrate processing device 101, a scanning electron microscope 102, and the like. The substrate processing device 101 is, for example, a device such as a process chamber that performs processing such as etching on a wafer (substrate) of a semiconductor. The processed substrate, which has been subjected to processing such as etching by the substrate processing device 101, has its surface shape or the like imaged by the scanning electron microscope 102. The scanning electron microscope 102 is a device that irradiates an object with an electron beam, and observes the object by detecting secondary electrons, transmitted electrons, or the like emitted from the object. The scanning electron microscope 102 outputs a so-called scanning electron microscope (SEM) image in which the object is imaged. The SEM image output from the scanning electron microscope 102 is supplied to the information processing device 1. In the present embodiment, processing is performed with respect to an SEM image captured by the scanning electron microscope 102 as a target. However, the processing is not limited thereto, and for example, processing may be performed with respect to an image captured by a transmission electron microscope, an optical microscope, or the like as a target.

Structures having various shapes are formed on a surface of the substrate subjected to substrate processing performed by the substrate processing device 101. For example, as in the SEM image illustrated in a middle of FIG. 1, a plurality of structures having the same shape may be formed on the substrate. Hereinafter, in the present embodiment, each structure having the same shape will be referred to as a pattern. However, in actuality, even if the formation of the patterns having the same shape is intended, sizes, shapes, and the like are different in each pattern due to processes such as film formation, etching, or exposure (herein “film” means the same as “layer”). A pattern whose size or shape deviates beyond a given threshold value is determined to be abnormal. The information processing system according to the present embodiment is a system that detects a plurality of patterns formed on a target substrate based on an SEM image of the target substrate captured by the scanning electron microscope 102, detects contours of detected patterns, and detects length measurement locations for each pattern based on the detected contours.

In the present embodiment, the substrate processing device 101, the scanning electron microscope 102, and the information processing device 1 will be described as separate devices. However, the present disclosure is not limited thereto. For example, the substrate processing device 101 and the scanning electron microscope 102 may be one device, the scanning electron microscope 102 and the information processing device 1 may be one device, and the substrate processing device 101, the scanning electron microscope 102, and the information processing device 1 may be one device. Each of the substrate processing device 101, the scanning electron microscope 102, and the information processing device 1 may be implemented by combining a plurality of devices.

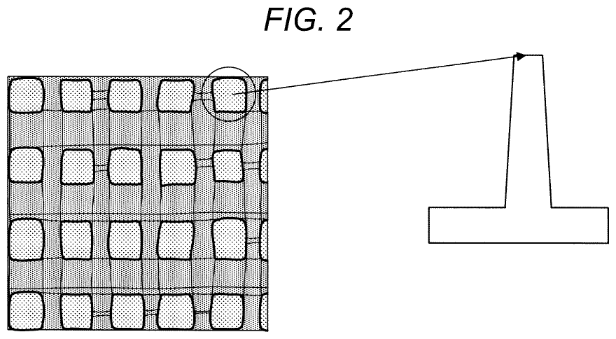

FIG. 2 is a schematic diagram illustrating a configuration example of a pattern formed on a substrate. An example of a captured image (SEM image) of the surface of the substrate imaged by the scanning electron microscope 102 is illustrated at a left side of FIG. 2, and this image corresponds to a configuration in a top view of the substrate. In the SEM image in the present example, a configuration in which a plurality of rectangular patterns indicated by thick black lines are arranged at substantially equal intervals vertically and horizontally is captured. Each rectangular pattern captured in the image is a structure that is a detection processing target. A side view of a target structure is schematically illustrated at a right side of FIG. 2. The target structure in the present example has a substantially rectangular upper surface and has a truncated quadrangular pyramid shape that gradually increases in thickness from an upper portion to a lower portion. A rectangle indicated by a thick black line in an image at the left side of FIG. 2 corresponds to an inclined portion of the side surface of the structure illustrated at the right side of FIG. 2.

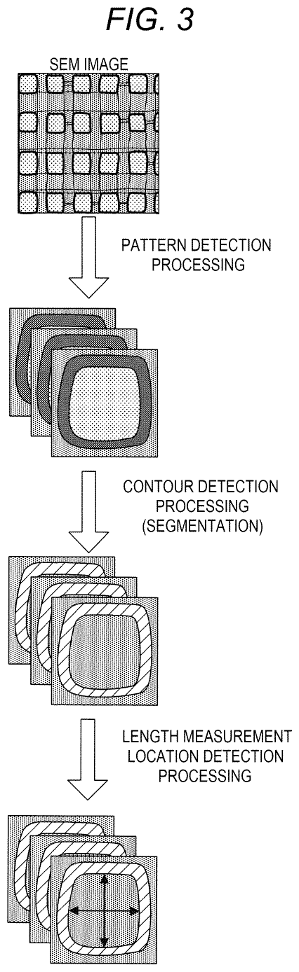

FIG. 3 is a schematic diagram illustrating an overview of detection processing performed by the information processing device 1 according to the present embodiment. The information processing device 1 according to the present embodiment acquires an SEM image obtained by imaging a target substrate with the scanning electron microscope 102, and first performs pattern detection processing on the SEM image. A plurality of patterns having the same shape may be formed on the target substrate, and a plurality of patterns having the same shape may be captured in the SEM image acquired by the information processing device 1. An example of the SEM image is illustrated at a top of FIG. 3, and a plurality of rectangular frames with thick black lines are vertically and horizontally arranged in the SEM image. In the present example, the structure having a shape of the rectangular frame is used as a target pattern, and the information processing device 1 performs detection processing.

In the present example, a plurality of patterns are captured in one SEM image, and the information processing device 1 acquires one SEM image and performs detection processing for each pattern. However, the present disclosure is not limited thereto. For example, the information processing device 1 may acquire a plurality of SEM images in which a plurality of target patterns are captured, and perform detection processing for the plurality of patterns captured in the plurality of SEM images. For example, the information processing device 1 may acquire a plurality of SEM images on which one target pattern is captured, and perform detection processing for the pattern captured in the plurality of SEM images.

The pattern detection processing performed by the information processing device 1 is processing of detecting, for example, a rectangular image region in which one pattern is captured, from an SEM image acquired from the scanning electron microscope 102. By detecting the pattern with respect to the acquired SEM image, the information processing device 1 can obtain information such as coordinates and size of a rectangular frame surrounding each pattern, i.e., a so-called bounding box, for one or more patterns captured in the SEM image. Based on results of the pattern detection processing, the information processing device 1 extracts an image region in which each pattern is captured by individually cutting out a region of the bounding box from the SEM image. A second image from the top of FIG. 3 illustrates a plurality of image regions of the target pattern extracted from the SEM image.

Next, the information processing device 1 performs contour detection processing on the target pattern for one or more image regions obtained as a result of the pattern detection processing. In the present embodiment, the contour detection processing performed by the information processing device 1 is processing of detecting pixels on which a target pattern is captured in the image region, i.e., so-called segmentation processing. Based on a result of the segmentation processing, the information processing device 1 can handle a plurality of pixels aligned outermost among the plurality of pixels in which the pattern is captured, as a contour of the pattern. The information processing device 1 performs segmentation processing on each image region obtained as a result of the pattern detection processing, and can obtain information indicating pixels in which the target pattern is captured, i.e., a so-called mask image, is obtained as a result of the contour detection processing. A third image from the top of FIG. 3 illustrates a mask image obtained through contour detection which is superimposed on the image region of the target pattern.

Next, the information processing device 1 performs processing to detect a length measurement location of each pattern, based on the mask image that indicates pixels in which each pattern is captured, which is obtained as a result of the contour detection processing. Even if a plurality of patterns formed on the substrate are intended to be formed in the same shape in design, differences in size, shape, or the like occur for each pattern due to a process such as film formation, etching, or exposure. In the information processing system according to the present embodiment, a length of a specific location of each pattern is measured to determine whether the pattern on the substrate is formed in a desired shape, based on whether the measured length is within a normal range. Length measurement location detection processing performed by the information processing device 1 is processing of detecting a location in each pattern where a length is to be measured to determine whether the pattern is normal or abnormal.

In a fourth image from the top of FIG. 3, two arrows indicating length measurement locations are illustrated superimposed on the image region of each pattern as a result of the length measurement location detection processing. Each arrow indicates a start point of the length measurement location at one end thereof, and indicates an end point of the length measurement location at the other end, and indicates a distance measured by a straight line distance connecting the start point and the end point. In the present example, two arrows are illustrated as the length measurement locations, and length measurements are performed at two locations for one pattern. That is, in the present example, a vertical length and a horizontal length in the frame are measured for each pattern illustrated by the rectangular frame with the thick black line. As a result of the length measurement location detection processing, the information processing device 1 can obtain a length measurement location image in which an index such as an arrow indicating a length measurement location is drawn, or coordinate information on a start point and an end point of the length measurement location in the image region of each pattern, and the like.

Next, the information processing device 1 performs processing of measuring a length of the location based on the length measurement location image or the coordinate information of the length measurement location obtained as the result of the length measurement location detection processing. The information processing device 1 detects an index such as an arrow drawn in the length measurement location image of each pattern obtained as a result of the length measurement location detection processing, calculates a length between two ends of the detected arrow or the like, and acquires information such as a magnification when the scanning electron microscope 102 captures an image, to calculate an actual length of the length measurement location. The information processing device 1 can determine whether the pattern is normal or abnormal, based on whether the length is within the given range, by comparing a measured length with threshold values such as a predetermined upper limit value and lower limit value.

In this way, in the information processing system according to the present embodiment, the information processing device 1 performs pattern detection processing, contour detection processing, and length measurement location detection processing based on the SEM image of the substrate captured by the scanning electron microscope 102, and determines whether the pattern is normal. When the information processing device 1 performs the detection processing, a user needs to set information such as a detection condition for the information processing device 1. For example, in the pattern detection processing, the user sets, as a detection condition in the information processing device 1, which of many patterns captured in the SEM image is a detection target. For example, in the contour detection processing, the user sets which pattern is the target pattern for detecting a contour, i.e., from which location the mask image that is a result of the segmentation processing is desired to be obtained. For example, in the length measurement location detection processing, the user sets information as to which location of the target pattern is to be set as a length measurement location.

The information processing system according to the present embodiment has a function of supporting an input of information such as a condition related to the detection processing, so as to facilitate use of the system by the user and improve convenience of the system. The information processing device 1 receives an input of information using text of a natural language from a user by using a training model for which machine learning has been performed in advance, for example, a large language model (LLM), and determines a detection processing condition based on the received information, and performs detection processing according to the determined condition. In addition to information input in a natural language, the information processing device 1 receives an input of information based on, for example, designation of coordinates or a region for a displayed image, and performs detection processing. Hereinafter, in the present embodiment, information input by a user in the natural language and information input by designating coordinates or a region for an image is referred to as information input by a “prompt”, and the information to be input is referred to as a “prompt”. The prompt may include an information input other than the natural language, coordinate designation, and region designation described above.

In the information processing system according to the present embodiment, an information input based on the prompt described above is received in the three types of detection processing: the pattern detection processing, the contour detection processing, and the length measurement location detection processing performed by the information processing device 1. The information processing system may be configured to receive an information input based on the prompt in at least one of the three types of detection processing among the pattern detection processing, the contour detection processing, and the length measurement location detection processing.

### <Device Configuration>

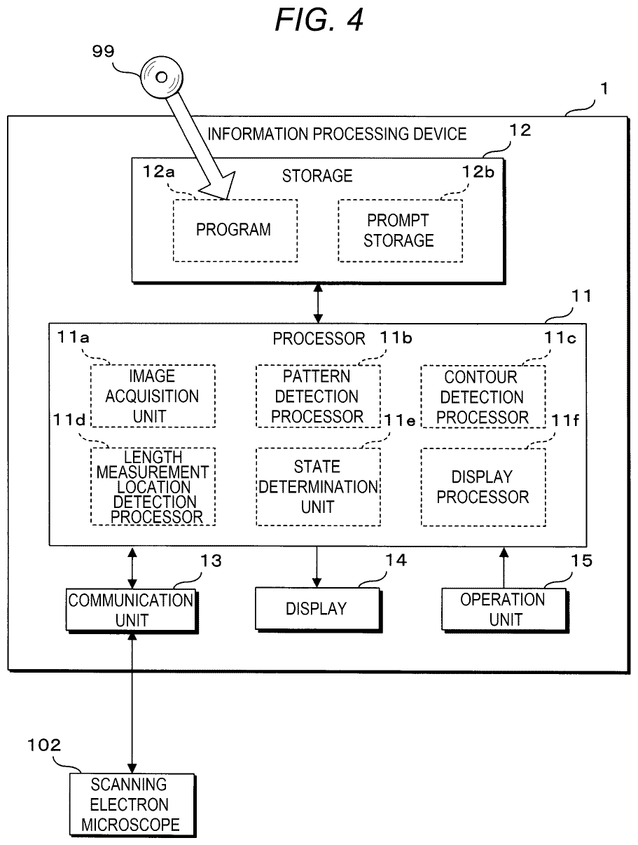

FIG. 4 is a block diagram illustrating a configuration example of the information processing device 1 according to the present embodiment. The information processing device 1 according to the present embodiment can be implemented by installing a given application program or the like in a general-purpose information processing device such as a personal computer or a server computer (herein “computer” means the same as “controller circuitry”). The information processing device 1 may be an information processing device dedicated to controlling the substrate processing device 101 or the scanning electron microscope 102. The information processing device 1 according to the present embodiment includes a processor 11 (herein “processor” means the same as “controller circuitry”), a storage 12, a communication unit 13, a display 14, an operation unit 15, and the like (herein “unit” means the same as “circuitry”). In the present embodiment, an example will be described in which a process is performed by one information processing device 1. Meanwhile, the process of the information processing device 1 may be distributed and performed by a plurality of devices.

The processor 11 is configured by using an arithmetic processing device such as a central processing unit (CPU), a micro-processing unit (MPU), a graphics processing unit (GPU), or a quantum processor, a read only memory (ROM), a random access memory (RAM), and the like. The processor 11 reads and executes the program 12a stored in the storage 12, thereby performing various types of processing such as processing for detecting a pattern from an SEM image on a substrate, processing for detecting pixels on which a detected pattern is captured, and processing for detecting a measurement location for the detected pattern. The processor/controller circuitry 11 can be programmable circuitry (e.g., embedded processor) or fixed circuitry (e.g., ASIC or PAL). In an exemplary embodiment, the processor/controller circuitry 11 can include one or more programmable processors/controllers.

The storage 12 is configured by using, for example, a large-capacity storage device such as a hard disk or a solid state drive (SSD). The storage 12 stores various types of programs to be executed by the processor 11 and various types of data necessary for the process of the processor 11. In the present embodiment, the storage 12 stores the program 12a to be executed by the processor 11. The storage 12 includes a prompt storage 12b that stores and accumulates information on prompts input by a user when the detection processing is performed.

In the present embodiment, the program (computer program, program product) 12a is provided in a form recorded on a recording medium 99 such as a memory card or an optical disc (herein “computer program” means the same as “executable instructions”). The information processing device 1 reads the program 12a from the recording medium 99, and stores the program 12a in the storage 12. However, for example, the program 12a may be written into the storage 12 during a manufacturing stage of the information processing device 1. For example, as the program 12a, the information processing device 1 may acquire those which are distributed by a remote server device or the like through communication. For example, the program 12a may be written into the storage 12 of the information processing device 1 after a writing device reads data recorded in the recording medium 99. The program 12a may be provided in the form of distribution through a network, or may be provided in the form recorded in the recording medium 99.

The prompt storage 12b stores prompt information input by a user in the detection processing of the pattern detection processing, the contour detection processing, and the length measurement location detection processing. The prompt information includes text information in a natural language, or information such as coordinates or regions designated by the user for the image. The prompt storage 12b stores, in addition to the information of the input prompt, various types of information, such as information indicating which detection processing the prompt relates to, time stamp information such as date and time when the input of the prompt is received, input information such as an image that is a target of the detection processing performed based on the prompt, and/or output information such as an image that is a result of the detection processing performed based on the prompt, in association with each other. When receiving an input of prompt information from the user during the detection processing, the information processing device 1 reads past prompt information from the prompt storage 12b and displays a list, and can receive an input of prompt information by receiving a selection by the user from these.

The communication unit 13 is connected to the scanning electron microscope 102 via a cable such as a communication line or a signal line, and transmits and receives data to and from the scanning electron microscope 102 via the cable. In the present embodiment, the communication unit 13 receives data of an SEM image of a substrate transmitted from the scanning electron microscope 102, and supplies the received data to the processor 11. In the present embodiment, transfer of the SEM image from the scanning electron microscope 102 to the information processing device 1 via communication is performed. However, the transfer of the SEM image may be performed via, for example, a recording medium such as a memory card.

The display 14 is configured by using a liquid crystal display or the like, and displays various images, characters, and the like based on the process of the processor 11. In the present embodiment, the display 14 displays, for example, an SEM image acquired from the scanning electron microscope 102, and displays information on a result of the detection processing performed on the SEM image.

The operation unit 15 receives a user operation and notifies the processor 11 of the received operation. For example, the operation unit 15 receives the user operation by an input device such as a mechanical button or a touch panel provided on a surface of the display 14. For example, the operation unit 15 may be an input device such as a mouse and a keyboard, and these input devices may be configured to be detachable from the information processing device 1.

The storage 12 may be an external storage device connected to the information processing device 1. The information processing device 1 may be a multi-computer including a plurality of computers, or may be a virtual machine virtually constructed by software. In addition, the information processing device 1 is not limited to the configuration described above, and does not need to include the display 14, the operation unit 15, and the like, for example.

In the information processing device 1 according to the present embodiment, the processor 11 reads and executes the program 12a stored in the storage 12, thereby implementing an image acquisition unit 11a, a pattern detection processor 11b, a contour detection processor 11c, a length measurement location detection processor 11d, a state determination unit 11e, a display processor 11f, and the like as software functional units in the processor 11. In the drawing, the functional units related to the detection processing based on the SEM image are illustrated as the functional units of the processor 11, and the functional units related to other processing are omitted.

The image acquisition unit 11a performs processing for acquiring an SEM image captured by the scanning electron microscope 102 from a substrate processed by the substrate processing device 101. The image acquisition unit 11a communicates with the scanning electron microscope 102 by the communication unit 13 to acquire an SEM image of the substrate captured by the scanning electron microscope 102, and stores the acquired SEM image in the storage 12.

The pattern detection processor 11b performs processing for detecting one or more patterns formed on the substrate from the SEM image of the substrate acquired by the image acquisition unit 11a. For example, the pattern detection processor 11b displays the SEM image acquired by the image acquisition unit 11a on the display 14, and receives designation of a partial image region from the SEM image by the user to acquire the partial image region as a template image. The pattern detection processor 11b may acquire the template image by receiving a selection from the user from one or more template images stored in the prompt storage 12b. The pattern detection processor 11b detects one or more patterns from the SEM image by performing, for example, template matching processing, using a structure and the like captured in the acquired template image as the detection target pattern.

Template matching is a method of extracting an image region having the same size as a template image from a target image (SEM image), and when similarity between the extracted image and the template image exceeds a threshold value, determining that a detection target pattern is captured in this image region. By moving an extraction position of the image region from the target image and repeating similar similarity determination, and extracting the image region and determining similarity at all positions of the target image, one or more patterns can be detected from the target image. A method by which the pattern detection processor 11b detects a pattern from an SEM image based on a template image is not limited to the above-described template matching method, and various other methods may be adopted. For example, the pattern detection processor 11b can extract a feature point from a template image, extract a feature point from an SEM image, and perform matching of the feature points in the two images, thereby detecting one or more patterns from the SEM image.

In the present embodiment, the pattern detection processor 11b can receive an input of a prompt from a user when acquiring a template image in which a pattern that is a detection target is captured, and acquire the template image according to the input prompt. The prompt may be, for example, text in which shape features of a detection target pattern are described in a natural language. The text received as the prompt in the present embodiment does not need to be complete with a subject, object, and predicate, and may include, for example, a single word such as “square” or incomplete text such as a list of multiple words. The prompt may be, for example, region designation for designation that surrounds a detection target pattern on the SEM image, coordinate designation of one or more pixels in the detection target pattern, or coordinate designation of one or more pixels not in the detection target pattern.

The pattern detection processor 11b uses a training model such as an LLM subjected to machine learning in advance to acquire a template image according to an input prompt, and detects an identical pattern as a pattern captured in the template image from the SEM image. For example, the pattern detection processor 11b extracts one or more image regions in which the detected patterns are captured from the SEM image, and outputs the extracted one or more image regions as a detection result of the pattern. For example, the pattern detection processor 11b may output coordinate information of a bounding box surrounding the pattern detected from the SEM image as the detection result of the pattern.

The contour detection processor 11c performs processing for detecting a contour of each pattern with respect to one or more patterns detected from the SEM image by the pattern detection processor 11b. In the present embodiment, the contour detection processor 11c detects a contour of the pattern by performing so-called segmentation processing. The contour detection processor 11c uses a general-purpose trained training model for performing segmentation on an image, such as a segment anything model (SAM), to perform segmentation processing on the image region of each pattern detected by the pattern detection processor 11b, thereby detecting a contour of the pattern captured in the image region. Based on a result of the segmentation processing, the contour detection processor 11c creates a mask image that indicates a pixel in which the pattern is captured in the image region, and outputs the mask image as a result of the contour detection processing.

In the present embodiment, the SAM used by the contour detection processor 11c in the segmentation processing is a training model subjected to machine learning in advance to receive an input of an image and a prompt and perform object segmentation according to the prompt with respect to the input image. For example, the contour detection processor 11c may receive from a user an operation of designating a pixel in a detection target pattern (i.e., a detection target pattern is captured), an operation of designating a pixel not in the detection target pattern (i.e., a detection target pattern is not captured), or the like, and may use coordinate information in a designated image region as prompt information. The contour detection processor 11c may receive, from a user as a prompt, text information in which features related to a target pattern is described in a natural language. The contour detection processor 11c inputs the image region obtained as a result of the pattern detection and the prompt information received from the user into the SAM, and acquires a mask image of a segmentation result output by the SAM, thereby detecting a contour of the pattern from the image region.

When a plurality of image regions are extracted from the SEM image by the pattern detection processing, the contour detection processor 11c individually performs contour detection on the plurality of image regions. In the present embodiment, when performing the contour detection processing on the plurality of image regions, the contour detection processor 11c receives an input of a prompt from a user when performing the contour detection processing on a first image region, and performs the contour detection processing on second and subsequent image regions based on the prompt received related to the first image region and/or a result of the segmentation related to the first image region, without individually receiving an input of a prompt in the contour detection processing on the second and subsequent image regions.

The length measurement location detection processor 11d performs processing for detecting one or more length measurement locations for the pattern captured in each image region, based on the mask image of each pattern obtained as a result of the contour detection by the contour detection processor 11c. The length measurement location detection processor 11d outputs, for example, a length measurement location image in which an index such as an arrow or a straight line indicating a position of a length measurement location is drawn for each pattern captured in the image region, or coordinate information of pixels in the image region serving as a start point and an end point of the length measurement, as a detection result of the length measurement location.

In the present embodiment, the length measurement location detection processor 11d uses a length measurement location detection model subjected to machine learning in advance to receive a mask image obtained as a result of the contour detection processing and information on a prompt such as text or coordinates as an input and to output a length measurement location image (or coordinate information on a length measurement location) in which an index such as an arrow or a straight line indicating a length measurement location is drawn for the input mask image. The length measurement location detection model may be achieved, for example, by changing a part of the SAM used for the segmentation processing described above (changing to output a length measurement location image, coordinates of a length measurement location, or the like instead of outputting a mask image).

For example, the length measurement location detection processor 11d receives text information in which a length measurement location for a pattern is described in a natural language as a prompt from the user, inputs a mask image as a contour detection result of the pattern into the length measurement location detection model, and acquires information such as a length measurement location image or coordinates of a length measurement location output by the length measurement location detection model, thereby detecting a length measurement location. When a plurality of patterns are detected from the SEM image and a plurality of image regions and mask images are obtained, the length measurement location detection processor 11d receives an input of a prompt for a mask image of a first pattern from the user to perform length measurement location detection. The length measurement location detection processor 11d performs length measurement location detection processing for second and subsequent mask images, based on a prompt received for a first mask image and/or a detection result of a length measurement location for the first mask image, without individually receiving an input of a prompt for mask images of the second and subsequent patterns.

Regarding the mask image of the first pattern, instead of receiving the prompt based on the text, the length measurement location detection processor 11d may display, for example, a mask image corresponding to an image region in which a pattern is captured in a superimposed manner, and may receive designation of coordinates of a length measurement location for the image display from the user as the prompt. In this case, since the length measurement location is given as the prompt for the mask image of the first pattern, the length measurement location detection processor 11d does not need to detect the length measurement location using the length measurement location detection model related to the first mask image. The length measurement location detection processor 11d performs length measurement location detection processing related to the mask images of the second and subsequent patterns, based on a prompt input by the user (i.e., a length measurement location detection result for the mask image of the first pattern).

The state determination unit 11e performs processing for determining a state of the pattern based on the length measurement location detected by the length measurement location detection processor 11d. The state determination unit 11e detects an index such as an arrow or a straight line from the length measurement location image obtained as the length measurement location detection result, and calculates a length of the arrow based on, for example, coordinates of both ends of the arrow. Alternatively, the state determination unit 11e calculates a length (distance (e.g., in units of, for example, nanometers, micrometers, millimeters, centimeters, inches, etc.)) between a start point and an end point based on coordinate information on the start point and the end point obtained as a length measurement result. The state determination unit 11e calculates an actual length of the length measurement location of the pattern based on a calculated distance on the image region and information such as a magnification at the time of capturing the SEM image from which the image region is extracted. For example, the state determination unit 11e compares predetermined upper and lower limit values, or the like with the calculated length, and determines that the pattern is normal if the measured length is within a range of the upper and lower limit values, and determines that the pattern is abnormal if the measured length is outside the range. State determination of the pattern by the state determination unit 11e is not limited to the above-described method, and any state may be determined by any method.

The display processor 11f performs processing for displaying, on the display 14, information such as the SEM image acquired from the scanning electron microscope 102, the detection result by the pattern detection processor 11b, the contour detection processor 11c, and the length measurement location detection processor 11d for the SEM image, and state determination result of the pattern by the state determination unit 11e. For example, the display processor 11f generates an image in which a bounding box surrounding each pattern detected by the pattern detection processor 11b is superimposed on the SEM image acquired from the scanning electron microscope 102, and displays the generated image on the display 14. For example, the display processor 11f superimposes an image region of the pattern extracted from the SEM image based on a result of pattern detection and a mask image that is a result of contour detection performed on the image region, and displays a result of the contour detection on the display 14. For example, the display processor 11f displays a length measurement location image obtained as a result of the length measurement location detection processing on the display 14, or displays an index such as an arrow or a straight line, which indicates coordinates of a start point and an end point obtained as a result of the length measurement location detection processing, superimposed on an image as a result of the contour detection. For example, for each pattern detected from the SEM image, the display processor 11f displays, on the display 14, a length of the length measurement location, information indicating whether the length is normal or abnormal, and the like.

### Pattern Detection Processing

In the information processing system according to the present embodiment, the scanning electron microscope 102 images a substrate subjected to substrate processing such as etching by the substrate processing device 101, and the information processing device 1 acquires the captured image (SEM image) obtained through the imaging to determine a state of a pattern formed on the substrate. For this state determination, first, the information processing device 1 performs pattern detection processing for detecting a plurality of patterns formed on the substrate from an SEM image.

In the pattern detection processing, the information processing device 1 displays the SEM image acquired from the scanning electron microscope 102 on the display 14, and requests the user to input condition information related to the pattern to be detected, specifically, information for acquiring a template image in which a detection target pattern is captured. In response to this request, the user can perform an operation of designating a region surrounding one of detection target patterns on the displayed SEM image, for example. The information processing device 1 extracts an image region designated based on the operation of the user from an SEM image, and sets the extracted image region as a template image on which a detection target pattern is captured.

In the present embodiment, the information processing device 1 may receive an input of text in which, for example, a shape of the detection target pattern is described in a natural language, as the condition information for acquiring a template image, from the user. The information processing device 1 extracts a region from the SEM image on which a pattern corresponding to an input natural language text is captured, and uses the extracted image region as the template image. The natural language that the information processing device 1 receives as an input from the user is, for example, a character string such as a word or text in a language such as Japanese or English. In order to handle the natural language, the information processing device 1 according to the present embodiment uses an LLM subjected to machine learning in advance to interpret natural languages. The LLM may be operated by the information processing device 1, or may be operated by a device different from the information processing device 1, for example, a remote server device.

In the information processing system according to the present embodiment, for example, by inputting a natural language such as “hole” or “mask” to the information processing device 1, the user can display candidate images on which “hole”, “mask” or the like is captured, and can determine a template image by performing an operation of selecting one of these candidates. The user can display template image candidates with any modifiers such as an “elongated hole” or a “mask having a large size” on the information processing device 1.

The information processing device 1 extracts feature points from the SEM image acquired from the scanning electron microscope 102, and extracts appropriate image regions from the SEM image based on the extracted feature points, thereby creating candidates for template images. When a plurality of patterns having the same shape are repeatedly formed on the substrate, a plurality of feature points extractable from the SEM image may include a portion where disposition of similar feature points is repeated. The information processing device 1 searches for repetition of the disposition of similar feature points among the entire plurality of feature points extracted from the SEM image. The information processing device 1 can select any one location in the disposition of feature points repeated based on a search result, and extract a rectangular image region that includes the plurality of feature points in the disposition as a candidate for the template image. The information processing device 1 may extract a plurality of candidates from one SEM image. A method of extracting candidates by the information processing device 1 is not limited to the method described above, and any method may be adopted.

Feature point extraction processing is, for example, processing of specifying a feature point (pixel) such as an edge or a corner in an image, and may be performed using, for example, an existing method such as scale invariant feature transformation (SIFT) or Accelerated-KAZE (AKAZE). Each feature point extracted by the information processing device 1 from the image includes information on a position (e.g., x, y coordinates) of the feature point in the image and a numerical value (feature) indicative of a feature of the point.

The information processing device 1 that has extracted candidates for a template image from the SEM image selects candidates corresponding to the input natural language from the plurality of candidates, and displays a list of the selected candidates to present the list to the user. The information processing device 1 may select a template image corresponding to the input natural language from the template images stored in the prompt storage 12b, and display a list of the selected template images as candidates for presentation to the user. The information processing device 1 receives an operation of the user selecting any one of the plurality of candidates displayed in the list by the operation unit 15, and acquires the selected candidate as the template image.

For example, the information processing device 1 converts a natural language input by the user into a feature vector by an LLM, and converts a plurality of images to be candidates for the template image into a feature vector by a training model (encoder) subjected to machine learning in advance. The information processing device 1 calculates similarity between the input feature vector of the natural language and the feature vector of each candidate, selects a given number of candidates in descending order of similarity, and presents the selected candidates to the user. Accordingly, the information processing device 1 can present candidates corresponding to the natural language input by the user to the user. The training model for converting an image into a feature vector may be generated in advance through, for example, machine learning using training data in which a template image collected in advance and a natural language (or a feature vector obtained by converting the natural language into using an LLM) representing a pattern of the template image are associated with each other. A method of presenting candidates corresponding to natural languages to the user using the LLM described above is an example and is not limited thereto, and any other method may be adopted.

In the present embodiment, the condition information for acquiring an input from the user for the pattern as a detection target, such as the region designation information and natural language text information described above, is referred to as prompts, and the information processing device 1 stores and accumulates information on the input prompt in the prompt storage 12b. For example, the information processing device 1 stores, in the prompt storage 12b, information indicating that the prompt is a prompt for pattern detection processing, time stamp information such as date and time when the input of the prompt is received, and information such as a template image extracted from the SEM image based on the prompt, together with a prompt (such as a region designation or text) input during the pattern detection processing. The information processing device 1 may acquire a template image from the SEM image, acquire a template image stored in the prompt storage 12b, and allow the user to select which method to use to acquire the template image.

The information processing device 1 that has acquired the template image in which the detection target pattern is captured detects the identical pattern as the pattern captured in the template image from the SEM image. The information processing device 1 detects, for example, one or more identical patterns captured in the SEM image based on an existing template matching method. For example, the information processing device 1 may extract a feature point from a template image, extract a feature point from an SEM image, and perform matching of the feature points in the two images, thereby detecting one or more patterns from the SEM image. A method by which the information processing device 1 detects the identical pattern as the template image from the SEM image is not limited to the template matching or the feature point matching described above, and any method may be adopted.

The information processing device 1 that has detected one or more patterns captured in the SEM image by the pattern detection processing extracts an image region in which each detected pattern is captured from the SEM image. The image region of each pattern extracted from the SEM image serves as input information for subsequent contour detection processing.

When a template image is extracted from the SEM image based on a prompt of text information input by the user in the pattern detection processing, this processing of extracting the template image can be regarded as pattern detection processing for detecting a first pattern from the SEM image. Processing of detecting one or more patterns from the SEM image based on the template image can be regarded as second and subsequent pattern detection processing using a first pattern detection result. When the user designates a region for the SEM image to extract a template image, the region designation information by the user can be regarded as an input of a prompt for the pattern detection processing, and the extracted template image can be regarded as a detection result of the first pattern.

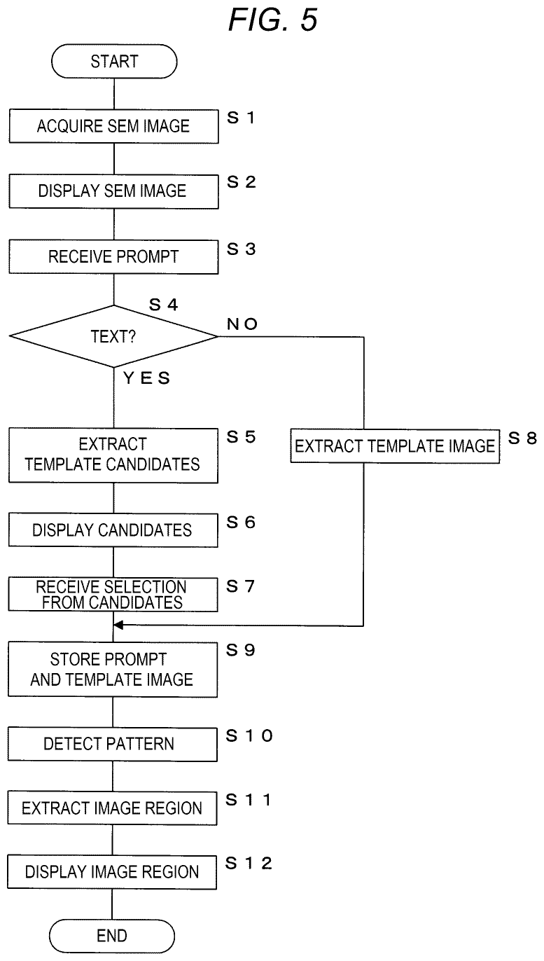

FIG. 5 is a flowchart illustrating an example of a procedure of pattern detection processing performed by the information processing device 1 according to the present embodiment. The image acquisition unit 11a of the processor 11 of the information processing device 1 according to the present embodiment communicates with the scanning electron microscope 102 by the communication unit 13, and acquires an SEM image of a target substrate captured by the scanning electron microscope 102 (step S1). The display processor 11f of the processor 11 displays the SEM image acquired by the image acquisition unit 11a in step S1 on the display 14 (step S2). The pattern detection processor 11b of the processor 11 receives an operation of a user on the operation unit 15, thereby receiving an input of a prompt (e.g., text information or region designation information) regarding a pattern to be detected (step S3).

The pattern detection processor 11b determines whether the prompt received in step S3 is text information (step S4). If the prompt is text information (S4: YES), the pattern detection processor 11b extracts candidates for a template image by extracting a plurality of image regions matching features of the text information from the SEM image acquired in step S1 using a training model such as an LLM based on the text information received as an input (step S5). The display processor 11f displays the candidates for the template image extracted in step S5 on the display 14 (step S6). The pattern detection processor 11b receives an operation of the user on the operation unit 15 to receive a selection of a candidate to be the template image from the plurality of candidates displayed on the display 14 (step S7), and proceeds the processing to step S9.

If the prompt received in step S3 is not text information (S4: NO), the pattern detection processor 11b extracts a region designated from the SEM image acquired in step S1 as the template image based on the region designation information input as the prompt (step S8), and proceeds to the processing to step S9.

The pattern detection processor 11b stores the prompt received in step S3 and the template image extracted based on the prompt, together with, for example, information indicating that the prompt is a prompt related to the pattern detection processing, and information such as time stamp information such as date and time when an input of the prompt is received, in the prompt storage 12b (step S9). The pattern detection processor 11b performs processing such as template matching or feature point matching based on the obtained template image, thereby detecting one or more patterns that match the template image from the SEM image (step S10). The pattern detection processor 11b extracts, from the SEM image, an image region in which the one or more patterns detected in step S10 are captured (step S11). The display processor 11f displays the image region of the one or more patterns extracted in step S11 on the display 14 (step S12), and ends the processing.

### Contour Detection Processing

The information processing device 1 acquires a plurality of image regions in which patterns are captured from the SEM image through the pattern detection processing, and performs processing of detecting a contour of a pattern for each image region. The information processing device 1 according to the present embodiment detects a contour of a pattern from the image region by performing processing of detecting pixels in which a pattern is captured in the image region, i.e., so-called segmentation processing. The information processing device 1 uses a trained contour detection model subjected to machine learning in advance to perform contour detection processing for each of a plurality of image regions obtained as a result of the pattern detection processing.

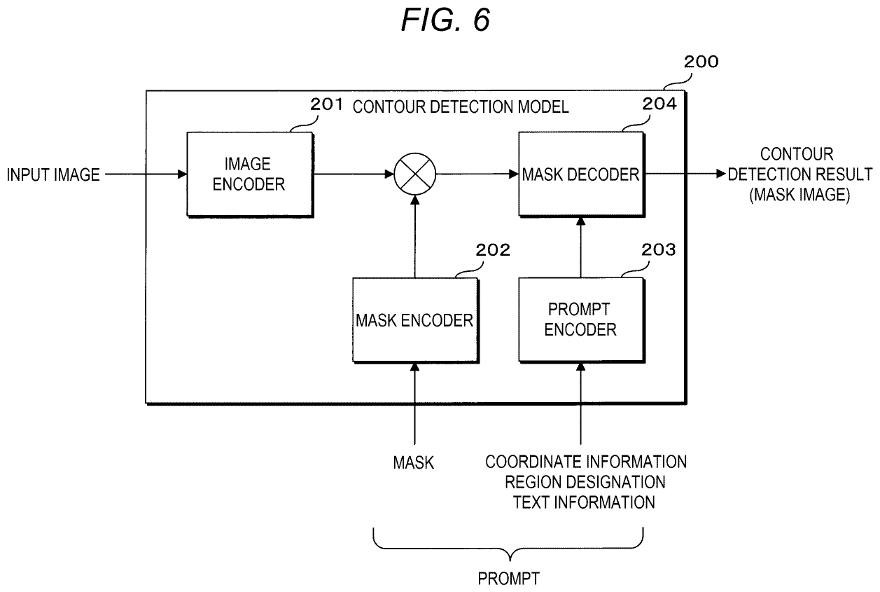

FIG. 6 is a schematic diagram illustrating a configuration example of a contour detection model according to the present embodiment. The contour detection model 200 used in the contour detection processing by the information processing device 1 according to the present embodiment is a training model that receives, as inputs, an input image and a prompt including various types of information on an object of segmentation, and outputs mask information indicating in which pixel the object is captured in the input image, as a contour detection result. As the contour detection model 200, for example, a training model that has been trained for performing segmentation such as an existing SAM is used.

The prompts input to the contour detection model 200 may include, for example, a mask image, coordinate information, region designation, and text information. In the present embodiment, it is not necessary to input a mask image as the prompt. The coordinate information input to the contour detection model 200 is, for example, information designating coordinates of one of a plurality of pixels in the object captured in the input image, or information designating coordinates of one of a plurality of pixels not in the object captured in the input image, for example. The region designation is information such as coordinates of a box (rectangular frame) that surrounds the object, for example, for designating a region where the object of segmentation is captured in the input image. The text information is information such as text or words in which a shape, color, or the like of an object of the segmentation is described in a natural language. The mask image input as the prompt is, for example, information designating a plurality of pixels in which a portion of the object of the segmentation in the input image is filled in, i.e., information designating a plurality of pixels in which the object is captured in the input image.

The contour detection model 200 according to the present embodiment includes an image encoder 201, a mask encoder 202, a prompt encoder 203, a mask decoder 204, and the like. The image encoder 201 performs processing for converting an input image into a feature. The mask encoder 202 performs processing for converting a mask image input as a prompt into a feature. A composite of the feature output from the image encoder 201 and the feature output from the mask encoder 202 is input to the mask decoder 204. The prompt encoder 203 performs processing for converting coordinate information, region designation, or text information input as the prompt into a feature. The mask decoder 204 performs processing for generating a mask image resulting from the segmentation for the input image, based on a feature obtained by combining an output from the image encoder 201 and an output from the mask encoder 202, and a feature output from the prompt encoder 203.

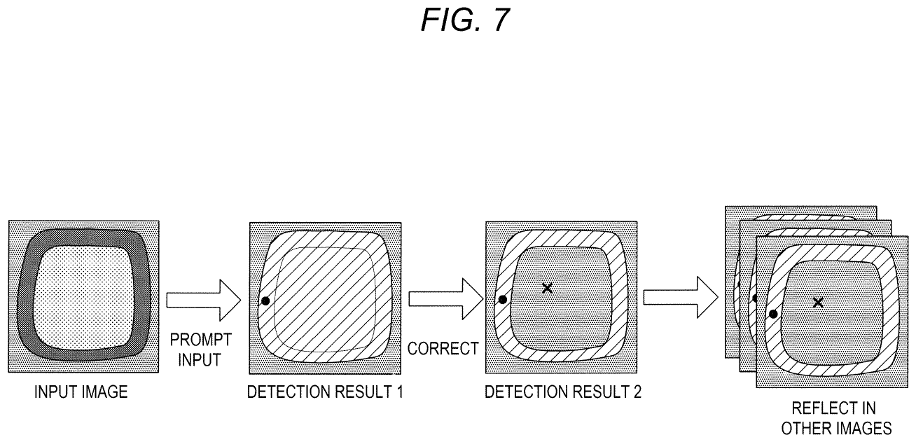

FIG. 7 is a schematic diagram illustrating an example of the contour detection processing. A first image from a left in FIG. 7 is an example of an input image for the contour detection processing, and is an example of an image region in which the pattern detected by the information processing device 1 through the pattern detection processing is captured. In the present example, the processing is performed with the purpose of detecting a contour of a thick black rectangular frame captured in the input image as a pattern. The information processing device 1 selects an appropriate one of a plurality of image regions of the pattern obtained as a result of the pattern detection processing, displays the selected image region on the display 14, and receives an input of a prompt from the user.

In the present example, the user inputs a prompt for designating coordinates of one point near a left end of the rectangular frame that is the detection target. The information processing device 1 receives an input of the prompt by the user, inputs the image region of the displayed pattern and the received prompt to the contour detection model 200, and acquires a mask image output by the contour detection model 200 in response thereto. An image with a detection result 1 illustrated in a second image from the left in FIG. 7 is an image in which the mask image of a processing result is superimposed on an image region of an original pattern and displayed on the display 14 by the information processing device 1. The detection result 1 in the present example includes an inside of a pattern of a target rectangular frame as the result of the segmentation processing (contour detection processing), and the user of the present example aims to make the pattern that does not include the inside of the rectangular frame as the result of the segmentation processing, and the detection result 1 is different from the result desired by the user.

In this case, the user can correct the detection result by additionally inputting a prompt. In the present example, the detection result is corrected by additionally inputting a prompt for designating the coordinates of one point of a pixel that is not in the detection target. An image with the detection result 2 illustrated at a third image from the left in FIG. 7 is a detection result corrected by an input of an additional prompt, and one point near a center of a region inside a rectangular frame is designated as an additional prompt for correction. The user can repeatedly correct the detection result obtained by the information processing device 1, and need not perform the correction by the user as long as a first detection result is desired.

The information processing device 1 stores, in the prompt storage 12b, information such as a prompt input from the user and a mask image obtained by contour detection based on the prompt. When inputting a prompt, the user can display a list of information such as prompts and mask images stored in the prompt storage 12b on the information processing device 1, and select one or more prompts from a plurality of stored past prompts to input a current prompt.

The information processing device 1 performs segmentation processing on one image region among a plurality of image regions obtained as a result of the pattern detection processing using the contour detection model 200 based on a prompt input from the user, and outputs a mask image obtained as a result of the processing as a contour detection result. The information processing device 1 according to the present embodiment performs contour detection processing for another image region by reflecting the prompt and the contour detection result for a first image region in the other image region. That is, for the second and subsequent image regions of the plurality of image regions obtained as a result of the pattern detection processing, the information processing device 1 according to the present embodiment can perform the contour detection processing based on the prompt acquired for the first image region and the mask image obtained as a detection result of a contour of the first image region, without a need to receive a new prompt input from the user.

Any of the following three methods (1) to (3) may be adopted as a method of performing the contour detection with respect to the second and subsequent image regions by reflecting the prompt and the contour detection result for the first image region.
(1) A method using a contour detection model using a contour detection result of a similar image as an input.
(2) A method of generating a prompt based on feature.
(3) A method of generating a prompt on a rule base.

### (1) Method Using Contour Detection Model Using Contour Detection Result of Similar Image as Input

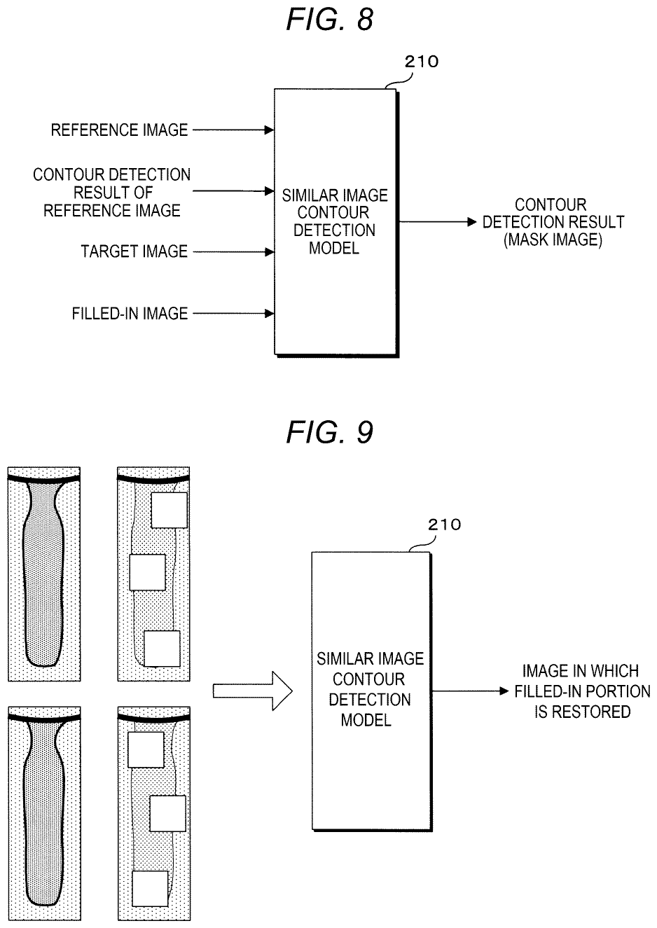

FIG. 8 is a schematic diagram illustrating a configuration example of a similar image contour detection model. A similar image contour detection model 210 used by the information processing device 1 according to the present embodiment for the contour detection processing for the second and subsequent image regions is a trained training model subjected to machine learning in advance to receive a reference image, a contour detection result of the reference image, a target image, and a filled-in image as inputs, and output a mask image that is a contour detection result of the target image. The reference image and the contour detection result of the reference image input to the similar image contour detection model 210 correspond to the first image region and the mask image obtained using the contour detection model 200 for this image region in the present embodiment. The target images input to the similar image contour detection model 210 correspond to the second and subsequent image regions that are detection targets in the present embodiment.

In the present embodiment, the filled-in image input to the similar image contour detection model 210 is an image in which the entire target image is filled in. The filled-in image is input information necessary for training of the similar image contour detection model 210. When making an inference using the similar image contour detection model 210, the information processing device 1 generates a filled-in image based on the target image and inputs the generated image into the similar image contour detection model 210.

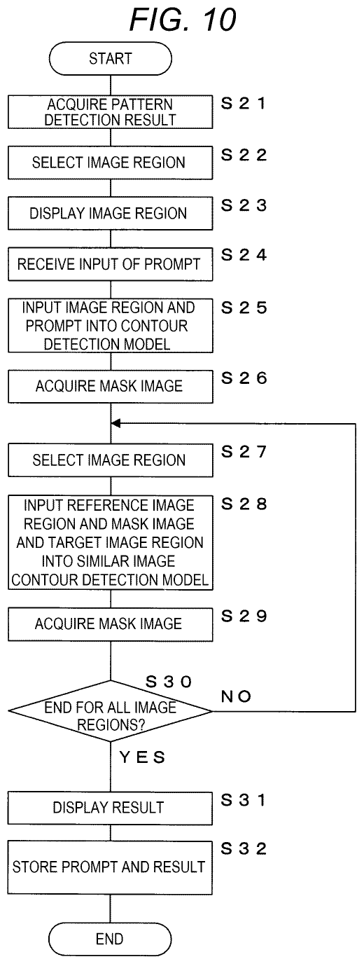

FIG. 9 is a schematic diagram illustrating an example of a training method of the similar image contour detection model 210. For machine learning of the similar image contour detection model 210, training data is prepared in advance, in which an image in which an object of contour detection processing (segmentation processing) is captured is associated with a mask image that is a contour detection result for this image. The information processing device 1 appropriately extracts two sets from a plurality of sets of the target image and the mask image, and generates a filled-in image in which a part of the mask image is filled in. In the illustrated example, the filled-in image is generated by filling three locations of the mask image with a rectangular region. However, this is an example, and the filled-in image may be generated by any method.

For the four pieces of input information of the similar image contour detection model 210, the information processing device 1 associates the input reference image as a first target image, the contour detection result of the reference image as a filled-in image generated based on a first mask image, the target image as a second target image, and the filled-in image as a filled-in image generated based on a second mask image. The information processing device 1 can perform machine learning of the similar image contour detection model 210 by associating contour detection results, which are output information from the similar image contour detection model 210, with the second mask image, and performing so-called supervised machine learning using these results as a ground truth value for input information. Machine learning processing of the similar image contour detection model 210 may be performed by, for example, a device different from the information processing device 1 such as a server device, instead of being performed by the information processing device 1.

The information processing device 1 uses the trained similar image contour detection model 210 to repeatedly perform contour detection processing for the second and subsequent image regions, and acquires a mask image as a result of the contour detection for each image region. In this repetition, as the reference image and the contour detection result thereof input to the similar image contour detection model 210, the information processing device 1 may use the first image region and the mask image thereof, or may use the image region and the mask image thereof used in previous contour detection processing.

### (2) Method of Generating Prompt Based on Feature

Based on a feature of the reference image (the first image region) and a feature of the target image (the second and subsequent image regions), the information processing device 1 generates a prompt for use in the contour detection processing of the target image. Accordingly, the information processing device 1 can obtain a mask image as the contour detection processing of the target image, based on the generated prompt and the contour detection model 200 illustrated in FIG. 6.

The information processing device 1 converts each of the reference image (the first image region) and the target image (the second and subsequent image regions) into feature information using, for example, an image encoder. The information obtained by the conversion is, for example, information obtained by giving a feature to each pixel in an image. The information processing device 1 compares the feature of the reference image and the feature of the target image, thereby performing processing for specifying a similar pixel between pixels in the reference image and pixels in the target image, i.e., so-called matching processing of feature points. Based on a result of the matching processing, the information processing device 1 determines which pixel in the target image corresponds to which pixel masked in the mask image for the reference image, and generates a prompt (e.g., coordinate designation or region designation) that causes the contour detection model 200 to detect a corresponding pixel in the target image.

The information processing device 1 can generate the prompt and generate a mask image based on the generated prompt, using, for example, an existing training model called Matcher, which is a technique derived from SAM. Matcher is a training model that performs segmentation using matching of features. However, since Matcher is an existing technique, a detailed description thereof will be omitted.

### (3) Method of Generating Prompt on Rule Base

For example, the information processing device 1 generates a prompt for the target image (the second and subsequent image regions) in accordance with a predetermined rule based on a prompt input by the user when performing the contour detection processing for the reference image (the first image region). The rules for generating the prompt may be, but are not limited to, the following.

When the prompt input by the user for the reference image is text information, the information processing device 1 uses the text information as it is as a prompt for the target image. When the prompt is coordinate designation or region designation, the information processing device 1 converts coordinates of the prompt for the reference image or the like into coordinates of the target image, assuming that the target image is the same size as the reference image. When the target image and the reference image have the same size, the information processing device 1 can use the prompts for the coordinate designation and the region designation as they are as the prompts for the target image.

When the contour detection is performed for the second and subsequent image regions by any of the methods (1) to (3) described above, the information processing device 1 displays, for example, a list of images on which mask images corresponding to the respective image regions are superimposed, on the display 14, as a contour detection result for the second and subsequent image regions. At this time, the information processing device 1 may display a list of contour detection results for the first image region and contour detection results for the second and subsequent image regions. The user can select one of the plurality of contour detection results displayed in the list to correct the contour detection result. For example, the user performs an operation of designating coordinates of a pixel in the pattern, designating coordinates of a pixel not in the pattern, or inputting a correction location as text. Upon receiving this operation, the information processing device 1 adds input correction information to the prompt, and re-executes the above-described contour detection processing to reflect the correction of the user for one image region in another image region.

FIG. 10 is a flowchart illustrating an example of a procedure of the contour detection processing performed by the information processing device 1 according to the present embodiment. The contour detection processor 11c of the processor 11 of the information processing device 1 according to the present embodiment acquires an image region of a detected pattern as a detection result of a pattern from the SEM image by the pattern detection processor 11b (step S21). The contour detection processor 11c appropriately selects one image region from a plurality of image regions acquired in step S21 (step S22). The display processor 11f of the processor 11 displays the image region selected in step S22 on the display 14 (step S23).

The contour detection processor 11c receives an operation on the operation unit 15, thereby receiving, from a user, an input of a prompt (information such as text information, coordinate designation or region designation) that is a condition for contour detection in the image region of the pattern displayed in step S23 (step S24). The contour detection processor 11c inputs the image region selected in step S22 and the prompt information received in step S24 into the contour detection model 200 illustrated in FIG. 6 (step S25). The contour detection processor 11c acquires a mask image, that is, information indicating which of pixels in which the pattern is captured is, output by the contour detection model 200 as a result of the contour detection according to the information input in step S25 (step S26).

The contour detection processor 11c selects one image region from the plurality of image regions acquired in step S21 that has not been selected (step S27). The contour detection processor 11c uses the image region selected in step S27 as a target image, the image region selected in step S22 as a reference image, and inputs the mask image acquired in step S26 as a contour detection result of the reference image into the similar image contour detection model 210 illustrated in FIG. 8 (step S28). At this time, the contour detection processor 11c uses a filled-in image input to the similar image contour detection model 210 as an image in which the entire target image is filled in. The contour detection processor 11c acquires a mask image that is output from the similar image contour detection model 210 as a result of the contour detection based on the information input in step S28 (step S29).

The contour detection processor 11c determines whether the contour detection processing has been ended for all the image regions acquired in step S21 (step S30). If the processing has not been ended for all the image regions (S30: NO), the contour detection processor 11c returns the processing to step S27, selects one of the unprocessed image regions, and repeats the contour detection. If the processing has been ended for all the image regions (step S30: YES), the display processor 11f displays, for example, an image in which a mask image is superimposed on the image region, on the display 14 as a result of the contour detection processing (step S31). The contour detection processor 11c stores, for example, the image region selected in step 22, the prompt received in step S24, and the mask image acquired in step S26, together with information such as information indicating that the information is related to the contour detection processing and time stamp information such as date and time when the input of the prompt is received, in the prompt storage 12b (step S32), and ends the processing.

### Length Measurement Location Detection Processing

The information processing device 1 acquires mask information indicating which pixel a pattern is captured from the image region in which the pattern is captured by the contour detection processing, and performs processing to detect a length measurement location for the pattern in each image region. The information processing device 1 according to the present embodiment acquires a plurality of sets of image regions and mask images related to the pattern, selects an appropriate set from the plurality of sets, and displays a superimposed image of the selected set of the image region and mask image on the display 14. The user inputs a prompt for designating a length measurement location for the displayed image.

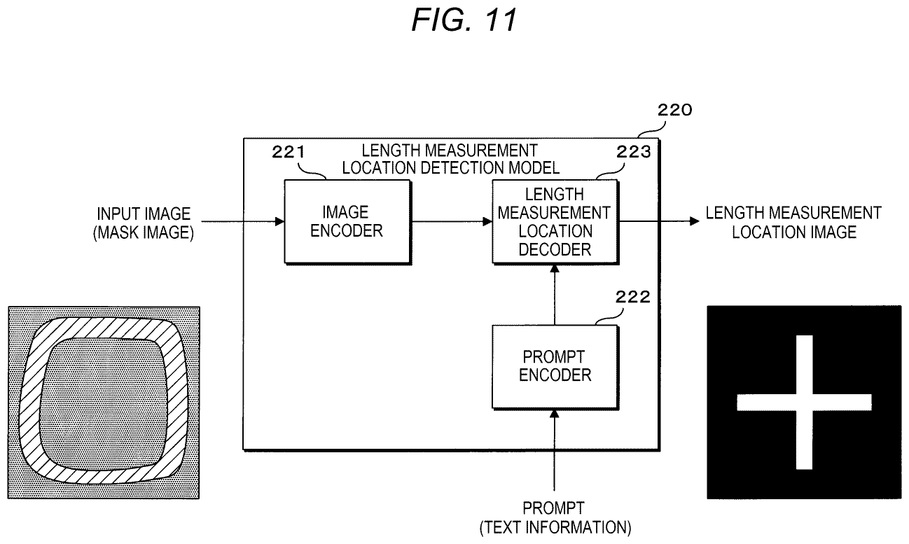

For example, when the user inputs text information in which features of a length measurement location are described in a natural language as a prompt, the information processing device 1 uses a trained length measurement location detection model subjected to machine learning in advance, and detects the length measurement location of the pattern based on a mask image of a target pattern and the input text information. FIG. 11 is a schematic diagram illustrating a configuration example of a length measurement location detection model based on text information. The length measurement location detection model 220 used in the length measurement location detection processing by the information processing device 1 according to the present embodiment is a training model that receives an input image and a prompt as inputs, and outputs, as a detection result, a length measurement location image in which an index such as an arrow or a straight line indicating a length measurement location for the input image is drawn. In the present embodiment, the prompt input to the length measurement location detection model 220 is text information, and the input image is a mask image of a pattern.

The length measurement location detection model 220 according to the present embodiment includes an image encoder 221, a prompt encoder 222, and a length measurement location decoder 223. The image encoder 221 performs processing for converting an input image into a feature. The prompt encoder 222 performs processing for converting text information input as a prompt into a feature. The length measurement location decoder 223 performs processing for generating a length measurement location image that is the detection result of the length measurement location for the input image, based on a feature output from the image encoder 221 and a feature output from the prompt encoder 222.

The length measurement location detection model 220 may be generated, for example, by replacing the mask decoder 204 of the contour detection model 200 illustrated in FIG. 6 (or an existing SAM training model or the like) with the length measurement location decoder 223 by retraining or the like. The length measurement location detection model 220 may be generated by performing so-called supervised machine learning and updating parameters of the length measurement location decoder 223 using training data obtained by associating a mask image as a contour detection result of a pattern, text information related to a length measurement location, and a length measurement location image in which an index such as an arrow that is a detection result of the length measurement location for the mask image is drawn.

The information processing device 1 inputs the mask image obtained as a result of the contour detection processing of the pattern and the text information input as a prompt from the user into the length measurement location detection model 220, and acquires the length measurement location image output by the length measurement location detection model 220 in response to the input, thereby detecting the length measurement location. The information processing device 1 may superimpose the length measurement location image on the image region and the mask image of the pattern as the detection result of the length measurement location, display the image on the display 14, receive a correction of a prompt from the user, and perform the length measurement location detection processing again based on the received prompt.

For example, when the user inputs coordinate information or the like in which a start point and an end point of the length measurement location are actually designated as the prompt, the information processing device 1 can handle the input coordinate information or the like as the prompt and can also handle the detection result of the length measurement location of the pattern captured in the first image region.

The information processing device 1 stores, in the prompt storage 12b, a prompt input from the user and information on a length measurement location based on the prompt. When inputting a prompt related to a length measurement location, the user can display a list of information such as prompts and length measurement locations stored in the prompt storage 12b on the information processing device 1, and select one or more prompts or length measurement locations from a plurality of stored past prompts and length measurement locations to input a current prompt.

Based on the mask image among the plurality of mask images obtained as a result of the contour detection processing and the text information prompt input from the user, the information processing device 1 performs length measurement location detection processing using the length measurement location detection model 220, and outputs a length measurement location image obtained from the length measurement location detection model 220 as a length measurement location detection result. When coordinate information of the length measurement location is input from the user as a prompt, the information processing device 1 generates an image in which an index such as an arrow or a straight line connecting coordinates of the start point and coordinates of the end point is drawn on a black background, a white background, or the like having the same size as a corresponding pattern, based on the input coordinate information, and uses this image as the length measurement location detection result.

The information processing device 1 displays, on the display 14, a detection result of a length measurement location based on the prompt when text information is input as a prompt, and can receive an operation of correcting the detection result from the user. At this time, the user may input the correction location as text information, or may input coordinate information on the length measurement location. When receiving an input of text information as the correction information, the information processing device 1 adds text information related to the correction to the text information prompt that has been acquired, and detects the length measurement location again using the length measurement location detection model 220, thereby correcting the detection result of the length measurement location. When receiving an input of coordinate information of a length measurement location as the correction information, the information processing device 1 can use this coordinate information as a new prompt and a new length measurement location detection result.

The information processing device 1 according to the present embodiment performs the length measurement location detection processing of another mask image by reflecting the length measurement location detection result of the mask image of the first pattern in the other mask image. That is, for the second and subsequent image regions of the plurality of image regions obtained as a result of the pattern detection processing, the information processing device 1 according to the present embodiment can perform the length measurement location detection processing based on the length measurement location image obtained as the length measurement location detection result related to the mask image of the pattern captured in the first image region, without a need to newly receive an input of a prompt from the user.

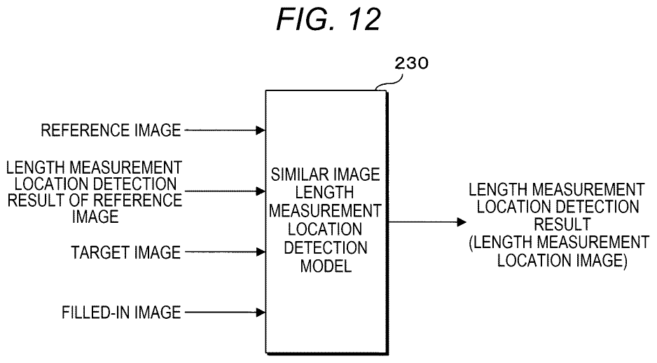

In the present embodiment, the information processing device 1 uses a length measurement location detection model to which the length measurement location detection result of a similar image is input, and performs length measurement location detection for mask images of the second and subsequent patterns. FIG. 12 is a schematic diagram illustrating a configuration example of a similar image length measurement location detection model. A similar image length measurement location detection model 230 used by the information processing device 1 according to the present embodiment for the length measurement location detection processing for the second and subsequent image regions is a trained training model subjected to machine learning in advance to receive a reference image, a length measurement location detection result of the reference image, a target image, and a filled-in image as inputs, and output a length measurement location image that is a length measurement location detection result of the target image. The reference image input to the similar image length measurement location detection model 230 and the length measurement location detection result of the reference image correspond to the mask image of the first pattern and the length measurement location image obtained using the length measurement location detection model 220 for this mask image in the present embodiment. The target image input to the similar image length measurement location detection model 230 corresponds to the mask image of the second and subsequent patterns that are detection targets in the present embodiment.

In the present embodiment, the filled-in image input to the similar image length measurement location detection model 230 is an image in which the entire target image is filled in. The filled-in image is input information necessary for training of the similar image length measurement location detection model 230. When making an inference using the similar image length measurement location detection model 230, the information processing device 1 generates a filled-in image based on the target image and inputs the generated image into the similar image length measurement location detection model 230.

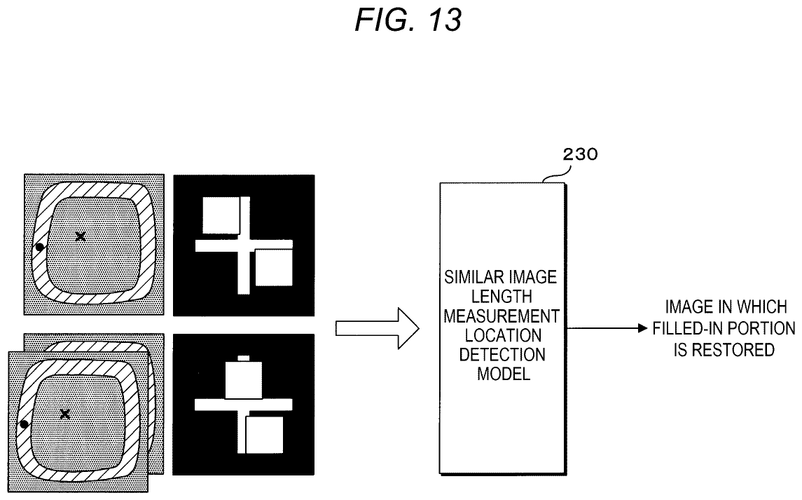

FIG. 13 is a schematic diagram illustrating an example of a training method of the similar image length measurement location detection model 230. For the machine learning of the similar image length measurement location detection model 230, training data is prepared in advance, in which a mask image obtained as a contour detection result of a pattern that is a target of the length measurement location detection processing is associated with a length measurement location image that is a length measurement location detection result for this image. The information processing device 1 appropriately extracts two sets from a plurality of sets of the mask image and the length measurement location image, and generates a filled-in image in which a part of the length measurement location image is filled in. In the illustrated example, the filled-in image is generated by filling two locations of the length measurement location image with a rectangular region. However, this is an example, and the filled-in image may be generated by any method.

For the four pieces of input information of the similar image length measurement location detection model 230, the information processing device 1 associates the input reference image as a first mask image, the length measurement location detection result of the reference image as a filled-in image generated based on a first length measurement location image, the target image as a second mask image, and the filled-in image as a filled-in image generated based on a second length measurement location image. The information processing device 1 can perform machine learning of the similar image length measurement location detection model 230 by associating length measurement location detection results, which are output information from the similar image length measurement location detection model 230, with the second mask image, and performing so-called supervised machine learning using these results as a ground truth value for input information. Machine learning processing of the similar image length measurement location detection model 230 may be performed by, for example, a device different from the information processing device 1 such as a server device, instead of being performed by the information processing device 1.

The information processing device 1 uses the trained similar image length measurement location detection model 230 to repeatedly perform length measurement location detection processing for the mask images of the second and subsequent patterns, and acquires a length measurement location image as a result of the length measurement location detection for each mask image. In this repetition, as the reference image and the length measurement location detection result thereof input to the similar image length measurement location detection model 230, the information processing device 1 may use the first mask image and the length measurement location image thereof, or may use the mask image and the length measurement location image thereof used in previous length measurement location detection processing.

The information processing device 1 displays a list of a plurality of length measurement location images on the display 14 as the length measurement location detection results for the second and subsequent image regions. At this time, the information processing device 1 may display a list of the length measurement location image for the mask image of the first pattern and the length measurement location images for the mask images of the second and subsequent patterns. The user can select one of the plurality of length measurement location images displayed in the list to correct the detection result of the length measurement location. For example, the user may input a correction location as text information, or may input coordinate information of a length measurement location to perform the correction. Upon receiving an operation of correction by the user, the information processing device 1 adds the input correction information to the prompt, and re-executes the above-described length measurement location detection processing to reflect the correction of the user for one length measurement location image in another length measurement location image.

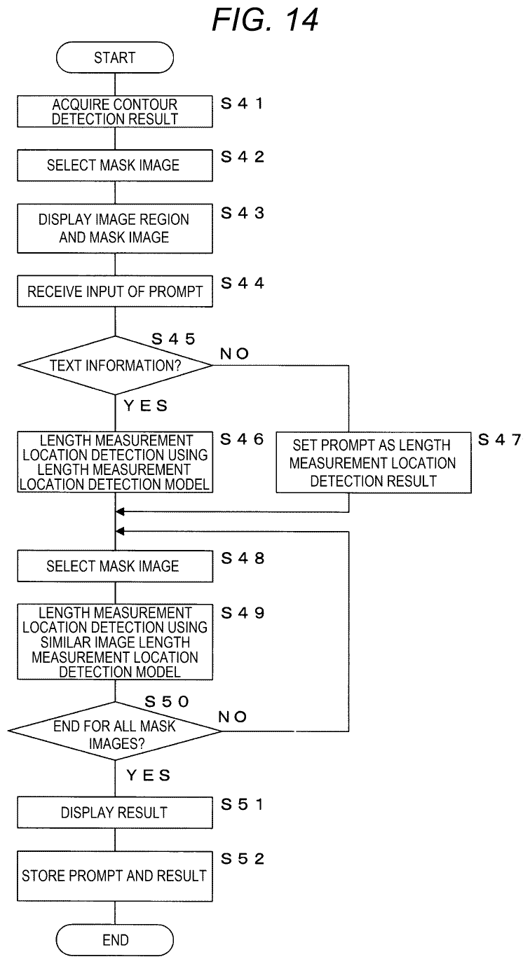

FIG. 14 is a flowchart illustrating an example of a procedure of the length measurement location detection processing performed by the information processing device 1 according to the present embodiment. The length measurement location detection processor 11d of the processor 11 of the information processing device 1 according to the present embodiment acquires a plurality of mask images corresponding to a plurality of patterns, respectively, as a contour detection result from an image region of the pattern obtained by the contour detection processor 11c (step S41). The length measurement location detection processor 11d appropriately selects one mask image from the plurality of mask images acquired in step S41 (step S42). The display processor 11f of the processor 11 superimposes the mask image selected in step S42 on an image region of a pattern corresponding to the mask image and displays the image region and the mask image on the display 14 (step S43).

The length measurement location detection processor 11d receives an operation on the operation unit 15, thereby receiving, from a user, an input of a prompt (information such as text information, coordinate designation or region designation) that is a condition for length measurement location detection for the image region and the mask image displayed in step S43 (step S44). The length measurement location detection processor 11d determines whether the prompt received in step S44 is text information (step S45). If the prompt is text information (S45: YES), the length measurement location detection processor 11d detects a length measurement location by the length measurement location detection model 220 illustrated in FIG. 11 based on the text information (step S46), and proceeds to step S48. In step S46, the length measurement location detection processor 11d can perform length measurement location detection processing by using the mask image selected in step S42 as an input image, inputting the text information received in step S44 as a prompt to the length measurement location detection model 220, and acquiring a length measurement location image output by the length measurement location detection model 220.

If the prompt is not the text information (step S45: NO), the length measurement location detection processor 11d sets the prompt as the detection result of the length measurement location because the prompt received in step S44 is coordinate information or the like in which the length measurement location is designated by the user (step S47), and proceeds to step S48.

The length measurement location detection processor 11d selects one mask image from the plurality of mask images acquired in step S41 that have not been selected (step S48). Based on the length measurement location detection result for the mask image selected in step S42, the length measurement location detection processor 11d performs length measurement location detection using the similar image length measurement location detection model 230 illustrated in FIG. 12 for the mask image selected in step S48 (step S49). At this time, the length measurement location detection processor 11d can detect a length measurement location by setting the mask image selected in step S48 as the target image, setting the mask image selected in step S42 as the reference image, setting the length measurement location image acquired in step S46 or a length measurement location image generated based on the length measurement location detection result in step S47 as the length measurement location detection result of the reference image, and inputting them to the similar image length measurement location detection model 230 to acquire a length measurement location image output by the similar image length measurement location detection model 230 as a length measurement location detection result. At this time, the length measurement location detection processor 11d uses a filled-in image input to the similar image length measurement location detection model 230 as an image in which the entire target image is filled in.

The length measurement location detection processor 11d determines whether the length measurement location detection processing has been ended for all the mask images acquired in step S41 (step S50). If the processing has not been ended for all the mask images (step S50:
NO), the length measurement location detection processor 11d returns the processing to step S48, selects one of the unprocessed mask images, and repeats the length measurement location detection. If the processing has been ended for all the mask images (step S50: YES), the display processor 11f displays the length measurement location image obtained as a result of the length measurement location detection on the display 14 (step S51). The length measurement location detection processor 11d stores, for example, the mask image selected in step 42, the prompt received in step S44, and the length measurement location image obtained as a result of the length measurement location detection processing in step S46, together with information such as information indicating that the information is related to the length measurement location detection processing and time stamp information such as date and time when the input of the prompt is received, in the prompt storage 12b (step S52), and ends the processing.

### Modification

The information processing device 1 may repeatedly perform length measurement location detection processing for the second and subsequent mask images using the length measurement location detection model 220 illustrated in FIG. 11, instead of a method using the similar image length measurement location detection model 230 illustrated in FIG. 12. It is assumed that the user inputs, for example, text information “to measure horizontal width at position 100 pixels below upper inner contour” as a prompt for designating a length measurement location for the mask image of the first pattern. In this case, the information processing device 1 inputs the mask image and the text information of the prompt input by the user into the length measurement location detection model 220, and acquires the length measurement location image output by the length measurement location detection model 220.

Next, the information processing device 1 according to the modification uses the same text information as the prompt for the second and subsequent mask images, inputs the same text information as the mask image to the length measurement location detection model 220, and acquires a length measurement location image output by the length measurement location detection model 220. By repeating similar processing for the second and subsequent mask images, the information processing device 1 according to the modification can obtain a detection result of a length measurement location for each pattern.

### State Determination Processing

The information processing device 1 according to the present embodiment performs processing of determining a state of a pattern detected from the SEM image, i.e., whether the pattern is normal or abnormal, based on a result of the length measurement location detection processing. Based on the result of the length measurement location detection processing, the information processing device 1 acquires coordinates of a start point and an end point of a length measurement location in a partial image in which the pattern is captured, and calculates a length of the length measurement location in the image based on the coordinates. The information processing device 1 stores information such as a magnification when the scanning electron microscope 102 images the substrate in advance, and calculates an actual length of the pattern based on the calculated length of the length measurement location and the magnification at the time of imaging.

After calculating the actual length at the length measurement location of the pattern, the information processing device 1 determines a state of the pattern by determining whether the calculated length is within a predetermined normal range. The information processing device 1 may perform state determination based on, for example, a comparison with a threshold value such as an upper limit value or a lower limit value set in advance by the user, or may determine the threshold value based on, for example, statistical values such as an average value and a variance value of lengths calculated for a plurality of patterns and perform the state determination based on a comparison with the determined threshold value, or may determine the threshold value by any other method.

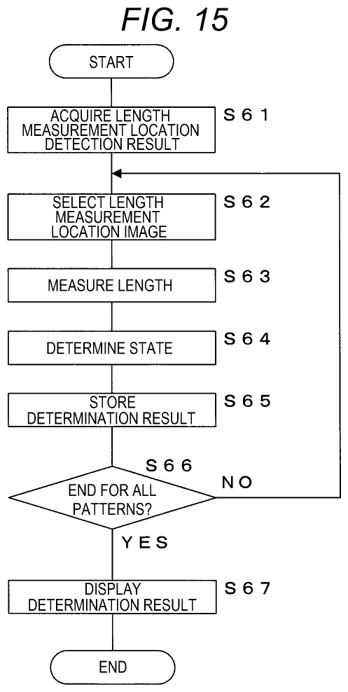

FIG. 15 is a flowchart illustrating an example of a procedure of the state determination processing performed by the information processing device 1 according to the present embodiment. The state determination unit 11e of the processor 11 of the information processing device 1 according to the present embodiment acquires a detection result of a length measurement location by the length measurement location detection processor 11d, i.e., a plurality of length measurement location images corresponding to a plurality of image regions extracted from the SEM image (step S61). The state determination unit 11e appropriately selects one length measurement location image from the plurality of length measurement location images acquired in step S61 (step S62). The state determination unit 11e measures a length of an index such as an arrow or a straight line drawn in the length measurement location image, for example, based on the length measurement location image selected in step S62, and calculates an actual length based on, for example, a magnification at the time of capturing the SEM image, thereby measuring a length of the pattern (step S63).

The state determination unit 11e determines a state of the pattern by determining whether the measured length is within a normal range based on a comparison between the length measured in step S63 and a predetermined upper limit value, lower limit value, or the like (step S64). The state determination unit 11e stores a result of the state determination performed in step S64 in the storage 12 (step S65).

The state determination unit 11e determines whether the state determination processing has been ended for all the patterns extracted from the SEM image (step S66). If the processing has not been ended for all the patterns (S66: NO), the state determination unit 11e returns the processing to step S62, selects one of the unprocessed length measurement location images, and repeats the state determination. If the processing has been ended for all the patterns (step S66: YES), the display processor 11f displays a result of the state determination on the display 14 by, for example, a method of displaying a list of the determination results as to whether the plurality of patterns detected from the SEM image are normal or abnormal (step S67), and ends the processing.

### <Summary>

In the information processing system according to the present embodiment having the configuration described above, the information processing device 1 performs detection processing related to a given pattern formed on a substrate subjected to substrate processing such as etching performed by the substrate processing device 101 on one or more captured images captured by the scanning electron microscope 102 on the substrate. The information processing device 1 performs pattern detection processing for detecting an image region in which a pattern is captured from the captured image, contour detection processing for detecting a contour of the pattern by segmentation processing for detecting a pixel in which the pattern is captured in the image region, and length measurement location detection processing for detecting a length measurement location for the pattern based on a result of the contour detection. In at least one type of detection processing of the pattern detection processing, the contour detection processing, and the length measurement location detection processing, the information processing device 1 according to the present embodiment acquires, as a prompt, condition information that includes at least one of coordinate information, region designation, or text information that is a detection condition, and performs the detection processing related to another pattern based on the acquired prompt related to the one pattern. Accordingly, the information processing system according to the present embodiment can be expected to support work of a user performing the detection processing because a frequency, amount, and the like at which the user is requested to input a condition and the like are reduced in the detection processing related to a plurality of patterns having a given shape formed on the substrate.

In the information processing system according to the present embodiment, the information processing device 1 performs contour detection processing related to a pattern having a given shape formed on a substrate subjected to substrate processing performed by the substrate processing device 101 on one or more captured images of the substrate captured by the scanning electron microscope 102. The information processing device 1 acquires an image region in which one pattern extracted from the captured image is captured, acquires condition information that includes at least one of coordinate information, region designation, or text information that is a detection condition, as a prompt, and performs contour detection processing related to another pattern based on the acquired prompt related to one pattern. Accordingly, the information processing system according to the present embodiment can be expected to support work of a user performing the contour detection processing because a frequency, amount, and the like at which the user is requested to input a condition and the like are reduced in the contour detection processing related to a given pattern formed on the substrate.

In the information processing system according to the present embodiment, the information processing device 1 inputs one image region and the prompt to a trained first segmentation model (contour detection model 200) that receives an image and a prompt as inputs and classifies (segments) a plurality of pixels configuring the image, and acquires a segmentation result output by the first segmentation model, thereby detecting a pixel in which a pattern is captured in the one image region, i.e., detecting a contour of the pattern. The information processing device 1 inputs the one image region, a segmentation result of the one image region, and another image region into a trained second segmentation model (similar image contour detection model 210) that receives a reference image, a segmentation result of the reference image, and a target image as inputs and performs segmentation of the target image, and acquires a segmentation result obtained by the second segmentation model, thereby performing contour detection of the pattern in the other image region. Accordingly, the information processing system according to the present embodiment can perform the contour detection for image regions of second and subsequent patterns only by a user inputting the prompt for an image region of a first pattern for a plurality of image regions extracted from an SEM image, and thus can be expected to support work of the user performing the contour detection processing.

In the information processing system according to the present embodiment, the information processing device 1 generates a prompt for the detection processing related to another pattern, based on the acquired prompt related to one pattern. The generation of the prompt may be performed using, for example, a training model that has been trained, or may be rule-based, for example, based on a predetermined rule. Accordingly, the information processing system according to the present embodiment can generate a prompt related to the second and subsequent patterns based on the prompt related to the first pattern, and perform detection processing for the second and subsequent patterns using the generated prompt, and thus can be expected to support work of the user performing the contour detection processing.

In the information processing system according to the present embodiment, the information processing device 1 inputs one image region and the prompt to a trained segmentation model (contour detection model 200) that receives an image and a prompt as inputs and classifies (segments) a plurality of pixels configuring the image, and acquires a segmentation result output by the segmentation model, thereby detecting a pixel in which a pattern is captured in the one image region, i.e., detecting a contour of the pattern. The information processing device 1 calculates a feature of each pixel for the one image region and the other image region, extracts similar pixels of the one image region and the other image region based on the calculated feature, and generates a prompt related to the other image region based on a segmentation result related to the one image region and the extracted similar pixels. Accordingly, the information processing system according to the present embodiment can be expected to generate a prompt for the image regions of the second and subsequent patterns, based on the prompt for the image region of the first pattern.

In the information processing system according to the present embodiment, the prompt received by the information processing device 1 includes information designating a pixel in the detected pattern or information designating a pixel not in the pattern. Accordingly, the information processing system according to the present embodiment can be expected to facilitate an operation of the user for designating a pattern that is a target for contour detection.

In the information processing system according to the present embodiment, the information processing device 1 displays (outputs) a result of the contour detection on the display 14, receives an input of correction information for the detection result from the user, and corrects the detection result based on the correction information. Accordingly, the information processing system according to the present embodiment can be expected to support the user in obtaining a desired detection result by correcting an input of a prompt serving as a detection condition through trial and error.

In the information processing system according to the present embodiment, the information processing device 1 receives an input of correction information for the detection result related to one pattern, and corrects a detection result related to another pattern based on the correction information. Accordingly, the information processing system according to the present embodiment can reflect correction performed by the user for one image region in an image region of another pattern when performing contour detection processing for many image regions, and thus can be expected to support correction work by the user.

In the information processing system according to the present embodiment, the information processing device 1 acquires a detection result of an image region in which a pattern is captured and a result of the contour detection of the pattern, acquires a prompt such as coordinate designation, region designation, or text information input by the user, and detects a length measurement location for the pattern based on the acquired detection result and prompt. The information processing device 1 also detects a length measurement location related to another pattern based on the acquired prompt related to the one pattern. Accordingly, the information processing system according to the present embodiment can be expected to support work of a user performing the length measurement location detection processing because a frequency, amount, and the like at which the user is requested to input a condition and the like are reduced in the length measurement location detection processing related to a plurality of patterns having a given shape formed on the substrate.

In the information processing system according to the present embodiment, the information processing device 1 performs length measurement location detection of one pattern by inputting a mask image of the one pattern and the prompt to a trained first length measurement location detection model (length measurement location detection model 220) that receives a detection result of the contour and the prompt as inputs and detects a length measurement location of the pattern and acquiring a length measurement location image output by the first length measurement location detection model. The information processing device 1 performs length measurement location detection of another pattern by inputting the mask image of the one pattern, a length measurement location result of the mask image of the one pattern, and a mask image of the other pattern to a trained second length measurement location detection model (similar image length measurement location detection model 230) that receives a reference image, a length measurement location detection result of the reference image, and a target image as inputs and detects a length measurement location of the target image, and acquiring a detection result of the length measurement location by the second length measurement location detection model. Accordingly, the information processing system according to the present embodiment can perform the length measurement location detection for mask images of second and subsequent patterns only by a user inputting a prompt for the mask image of the first pattern with respect to the contour detection result of each pattern captured in a plurality of image regions extracted from the SEM image, and thus can be expected to support work of the user performing the length measurement location detection processing.

In the information processing system according to the present embodiment, the information processing device 1 determines a state of the pattern formed on the substrate based on the length measurement location detection result. The information processing device 1 can measure a length of the pattern based on the detection result of the length measurement location of the pattern captured in the image region, and determine a state of the pattern based on, for example, whether a length measurement result is within a given range. Accordingly, the information processing system according to the present embodiment can be expected to accurately determine the state of each pattern formed on the substrate by the substrate processing device 101, based on the SEM image captured by the scanning electron microscope 102.

In the information processing system according to the present embodiment, the information processing device 1 stores, in the prompt storage 12b, a prompt input from the user as the condition information related to the detection processing, and instead of receiving a prompt directly from the user when performing the detection processing, acquires the prompt stored in the prompt storage 12b to perform the detection processing. Accordingly, the information processing system according to the present embodiment can be expected to support work of the user performing the detection processing because the user does not need to input a prompt again when performing the detection processing for, for example, a pattern similar to a pattern which is a target of the detection processing before.

In the present embodiment, for example, FIGS. 1 to 3, 7, 9, 11, and 13 schematically illustrate an SEM image in which an uneven portion formed on the substrate is captured, and processing performed by the information processing device 1 using the SEM image as the detection target pattern is described. However, the detection target pattern is not limited to such a three-dimensional structure in appearance. The pattern may be, for example, a plurality of functional elements such as transistors or capacitors formed on a substrate, or various formed objects such as thin films.

### Second Embodiment

### Contour Detection Processing

As described above, in the information processing system according to the present embodiment, the pattern detection processing, the contour detection processing, and the length measurement location detection processing are performed sequentially on the SEM image captured by the scanning electron microscope 102. An information processing system according to the second embodiment differs from the information processing system according to the first embodiment in a procedure of the contour detection processing among these types of processing. Procedures of the pattern detection processing and the length measurement location detection processing are the same for the information processing system according to the first embodiment and the information processing system according to the second embodiment.

In the information processing system according to the second embodiment, an image region of a pattern that is a target for contour detection and a mask image that is a contour detection result of this pattern are collected in advance. The collected image region of the pattern is converted into a feature, and a set of the image region of the pattern, the feature, and the mask image is stored and accumulated in a database. This database may be provided in the information processing device 1, or may be provided in a device different from the information processing device 1. However, at least the information processing device 1 can access the database via communication or the like.

The collection of image region or the like of the pattern stored in the database may be performed in advance by, for example, a designer of the information processing system according to the second embodiment. Alternatively, data obtained in the course of the contour detection processing or the like performed by the information processing system according to the first embodiment may be stored in the database.

The conversion of the image region of the pattern into the feature may be performed using, for example, a training model subjected to machine learning in advance. Since a technique of converting an image into a feature by using a training model is an existing technique, a detailed description thereof will be omitted.

The information processing device 1 of the information processing system according to the second embodiment converts an image region of a pattern obtained by pattern detection processing performed on an SEM image into a feature. The information processing device 1 calculates similarity (e.g., cosine similarity or L2 norm) between a converted feature and a feature of the image region of the pattern stored in the database, and acquires a set of the image region and the mask image of the pattern having the highest feature similarity from the database.

The information processing device 1 according to the second embodiment uses the image region and the mask image of the pattern acquired from the database, and the similar image contour detection model 210 illustrated in FIG. 8, to perform contour detection for an image region of a target pattern. That is, the information processing device 1 uses an image region of a similar pattern acquired from the database as a “reference image”, which is input information to the similar image contour detection model 210, uses a mask image acquired from the database as a “contour detection result of the reference image”, uses an image region of a pattern obtained by the pattern detection processing as a “target image”, and uses a mask image in which the entire target image is filled-in as a “filled-in image”. The information processing device 1 can detect a contour of the target pattern from an image region by inputting the information to the similar image contour detection model 210 and acquiring the mask image output by the similar image contour detection model 210.

When the contour cannot be detected by the method described above, or when an image region with a similar pattern is not stored the database, for example, the information processing device 1 according to the second embodiment receives an input of the prompt from the user and performs contour detection, similarly to the information processing device 1 according to the first embodiment. The information processing device 1 that receives a contour detection result based on the prompt input by the user stores, in the database, the image region of the pattern for which the contour detection has been performed, the feature of the image region, and the mask image that is a result of the contour detection, in association with each other.

As the similar image contour detection model 210 used by the information processing device 1 according to the first embodiment for the contour detection processing, for example, an existing training model that has been trained such as segGPT (Segmenting Everything in Context) can be adopted.

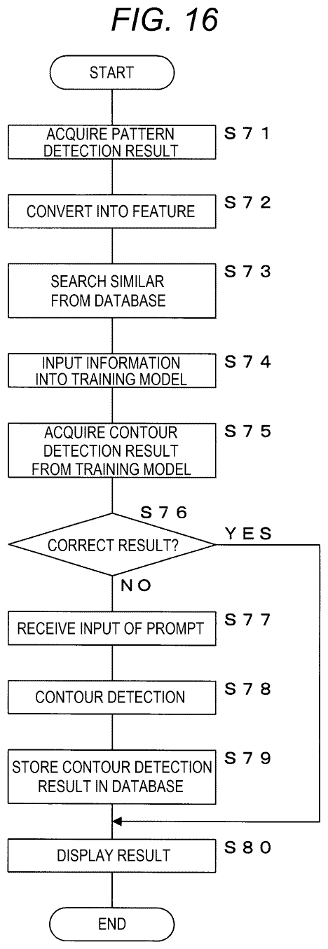

FIG. 16 is a flowchart illustrating an example of a procedure of the contour detection processing performed by the information processing device 1 according to the second embodiment. The contour detection processor 11c of the processor 11 of the information processing device 1 according to the second embodiment acquires an image region of a detected pattern as a detection result of a pattern from the SEM image by the pattern detection processor 11b (step S71).

The contour detection processor 11c converts the image region of the pattern acquired in step S71 into a feature (step S72). At this time, the contour detection processor 11c uses, for example, a training model subjected to machine learning in advance to convert the input image into the feature and output the feature, inputs the image region of the pattern into the training model, and acquires the feature that is output by the training model, thereby converting the image region of the pattern into the feature.

The contour detection processor 11c compares the feature converted in step S72 with the plurality of features stored in advance in the database, thereby searching the database for an image region similar to the image region of the pattern acquired in step S71 (step S73). At this time, for example, the contour detection processor 11c calculates similarity between the feature converted in step S72 and each feature stored in the database, and acquires the image region of the pattern corresponding to the feature having highest similarity and the mask image corresponding thereto from the database.

When a plurality of image regions are acquired for one pattern in step S71, the contour detection processor 11c may select at least one of these image regions as a representative, and perform conversion into a feature and search for a similar image region.

The contour detection processor 11c inputs the similar image region and mask image acquired from the database in step S73, and the image region of the pattern acquired in step S71 (and a filled-in image obtained by filling in the image) into the similar image contour detection model 210, which is a training model subjected to machine learning in advance (step S74). The contour detection processor 11c acquires a mask image as a contour detection result output from the similar image contour detection model 210 for the information input in step S74 (step S75).

Next, the contour detection processor 11c determines whether the contour detection result acquired in step S75 is a correct result (step S76). Here, for example, the contour detection processor 11c can calculate similarity between the mask image acquired in step S73 and the mask image acquired in step S76, and determine whether the contour detection result is correct based on whether the calculated similarity exceeds a predetermined threshold value. When calculating the similarity between the two mask images, for example, the contour detection processor 11c may convert the mask image into a feature to calculate cosine similarity, or may calculate the similarity by, for example, a template matching method, or may calculate Intersection over Union (IoU) of the two images as the similarity, or may calculate the similarity by any other method.

The contour detection processor 11c may determine whether the contour detection result is correct by a method other than the method described above based on similarity of the mask image. For example, when searching for the similar image region from the database in step S73, the contour detection processor 11c may determine that the contour detection result is not correct when a similar image region in which the similarity of the features exceeds a predetermined threshold value is not stored in the database.

For example, the contour detection processor 11c may determine whether the contour detection result is correct, using a training model generated in advance through machine learning. The training model is generated by so-called supervised machine learning using, for example, training data in which a mask image and a flag indicating whether the mask image is correct are associated with each other. The generated training model receives a mask image as an input, and outputs information indicating whether the mask image is correct. The contour detection processor 11c inputs the mask image acquired as the contour detection result in step S75 into the training model, and acquires information output from the training model, thereby being able to determine whether the mask image is correct.

If the contour detection result acquired in step S75 is correct (S76: YES), the display processor 11f of the processor 11 displays the contour detection result on the display 14 (step S80), and ends the contour detection processing.

If the contour detection result is not correct (step S76: NO), for example, the contour detection processor 11c displays the image region of the pattern acquired in step S71 on the display 14, and receives an input of a prompt containing information necessary for contour detection for this image region from the user (step S77). Based on the prompt received in step S77, the contour detection processor 11c performs the contour detection using, for example, the contour detection model 200 illustrated in FIG. 6 (step S78). The contour detection processor 11c stores, in the database, the mask image obtained as a result of the contour detection in step S78, together with the image region of the pattern acquired in step S71 and the feature of the image region (step S79). The display processor 11f displays the result of the contour detection in step S78 on the display 14 (step S80), and ends the contour detection processing.

### Modification

In the contour detection processing described above, the information processing device 1 extracts one image region similar to the image region of the pattern that is a target for contour detection from the database. However, the present disclosure is not limited thereto, and the information processing device 1 may extract a plurality of similar image regions.

In steps S73 to S76 of the flowchart illustrated in FIG. 16, the information processing device 1 acquires the image region and the mask image that are most similar to the image region of the target pattern from the database, performs the contour detection, and determines whether the contour detection result is correct. If it is determined in step S76 that the contour detection result is not correct, the information processing device 1 according to the modification acquires a next similar image region and mask image from the database, performs contour detection in the same manner, and determines whether the contour detection result is correct. The information processing device 1 according to the modification repeats acquisition of the image region and the mask image from the database in descending order of the similarity until a correct contour detection result is obtained, and for example, if it is determined that the contour detection result based on the image region and the mask image acquired from the database for a K-th time is not correct, performs contour detection based on a user input in steps S77 to S79. The above-described K is a natural number, and is predetermined by, for example, a designer of the information processing system according to the present embodiment.

The information processing device 1 according to the modification may acquire, instead of acquiring the image region and the mask image similar to the image region that is a contour detection target up to the predetermined K-th time, for example, a set of the image region and the mask image whose similarity is within a given range in descending order of similarity.

The information processing device 1 according to the modification may include, for example, the similar image contour detection model 210 configured to receive a plurality of reference images and contour detection results, and one target image and a filled-in image as inputs, and output a mask image that is a contour detection result of the target image. In this case, the information processing device 1 according to the modification can input a plurality of sets of the image region and the mask image acquired from the database into the similar image contour detection model 210, and acquire a contour detection result for a target image region.

### Method of Adding Information to Database

When a correct contour detection result is not obtained based on information stored in the database, the information processing device 1 according to the second embodiment receives a prompt input from the user to perform contour detection, and stores a contour detection result in the database. At this time, the information processing device 1 may store, in the database, a mask image in which the mask image as the contour detection result obtained based on the prompt input of the user is inverted. By using the mask image inverted as the contour detection result of the reference image input to the similar image contour detection model 210, accuracy of contour detection may be improved for the target image region.

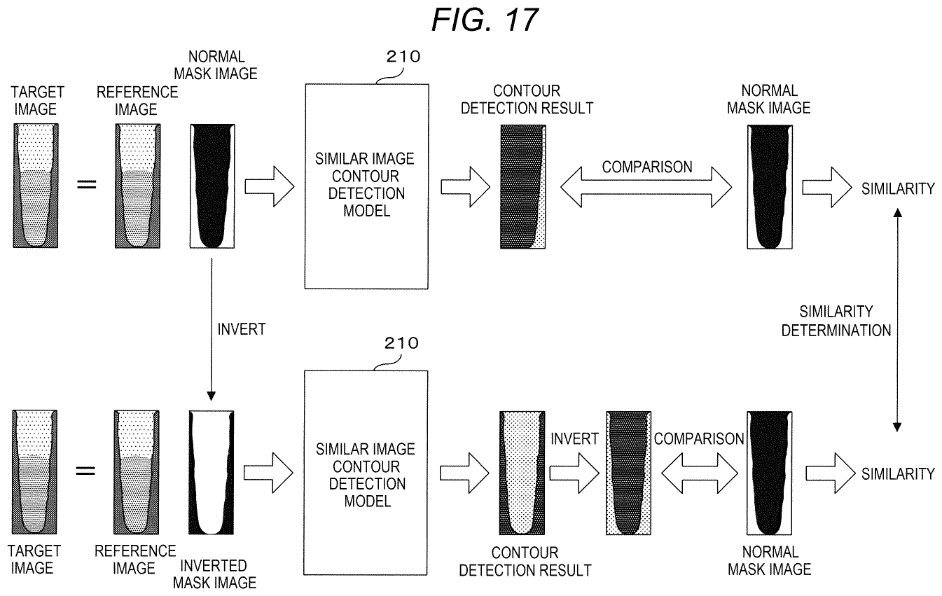

FIG. 17 is a schematic diagram illustrating a method of adding information to a database. As illustrated in FIG. 8, the similar image contour detection model 210 according to the present embodiment receives the reference image, the contour detection result (mask image) of the reference image, the target image, and the filled-in image as inputs, and outputs the mask image as the contour detection result of the target image. In step S78 of the flowchart illustrated in FIG. 16, the information processing device 1 acquires a mask image as the contour detection result for the image region of the pattern.

As illustrated in an upper portion of FIG. 17, the information processing device 1 inputs this image region as the target image and the reference image into the similar image contour detection model 210, and inputs the mask image (normal mask image) of this image region into the similar image contour detection model 210. In FIG. 17, a filled-in image input to the similar image contour detection model 210 is omitted from the drawing. The information processing device 1 acquires a mask image as the contour detection result output from the similar image contour detection model 210, and calculates similarity between the acquired mask image and the input normal mask image.

As illustrated in a lower portion of FIG. 17, the information processing device 1 generates an inverted mask image in which the normal mask image is inverted. The information processing device 1 inputs an original image region as the target image and the reference image into the similar image contour detection model 210, and inputs the inverted mask image into the similar image contour detection model 210. The information processing device 1 acquires a mask image as the contour detection result output from the similar image contour detection model 210, inverts the acquired mask image, and compares the inverted mask image and the normal mask image to calculate the similarity.

The information processing device 1 compares the similarity calculated based on the normal mask image with the similarity calculated based on the inverted mask image to determine whether to store the normal mask image or the inverted mask image. Appropriate values such as IoU or cosine similarity may be adopted as the similarity calculated by the information processing device 1.

When the similarity calculated based on the normal mask image is higher, the information processing device 1 stores the original image region and the normal mask image in association with each other in the database. When the similarity calculated based on the inverted mask image is higher, the information processing device 1 stores the original image region and the inverted mask image in association with each other in the database. At this time, the information processing device 1 may store information indicating that the mask image associated with the image region is the inverted mask image in the database together with the image region and the inverted mask image.

### User Interface

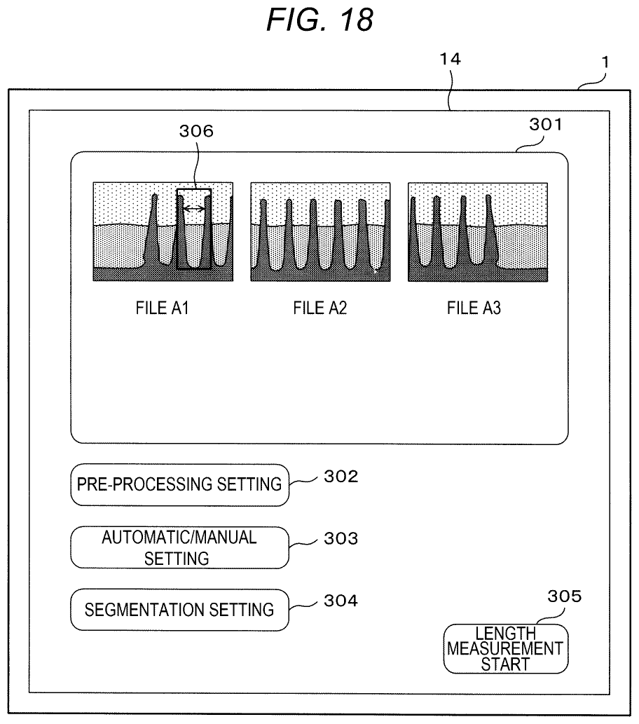

FIGS. 18 to 21 are schematic diagrams illustrating an example of a screen display by the information processing device 1 according to the present embodiment. The information processing device 1 according to the present embodiment displays, for example, an image file selection screen and receives a selection operation of an SEM image captured by the scanning electron microscope 102 from the user. The information processing device 1 reads files of the selected one or more SEM images and displays, for example, an initial screen illustrated in FIG. 18 on the display 14. In the initial screen displayed by the information processing device 1, for example, an image display region 301 for displaying a list of SEM images is provided in an upper portion of a screen, three buttons, that is, a pre-processing setting button 302, an automatic/manual setting button 303, and a segmentation setting button 304 are vertically arranged at a left side of a lower portion of the screen, and a length measurement start button 305 is provided at a lower right part of the lower portion of the screen.

The information processing device 1 displays the SEM image selected by the user and a file name thereof in association with each other in the image display region 301 of the initial screen. In the example illustrated in FIG. 18, three SEM images whose file names are “file A1”, “file A2”, and “file A3” are selected, and the information processing device 1 displays the three SEM images side by side in a horizontal direction in the image display region 301. The user can select a rectangular region for the SEM image displayed in the image display region 301 by using the operation unit 15 such as a mouse, for example, to select a pattern whose length is to be measured. In FIG. 18, a rectangular frame 306 that surrounds the pattern selected by the user is displayed in a superimposed manner on the SEM image. For example, the user can designate a length measurement location of the pattern by performing an operation of designating a start point and an end point in the rectangular frame 306 using the operation unit 15 such as a mouse. In FIG. 18, a two-way arrow 307 indicating a length measurement location designated by the user is displayed in a superimposed manner on the SEM image.

The pre-processing setting button 302, the automatic/manual setting button 303, and the segmentation setting button 304 provided in the initial screen are buttons for the information processing device 1 to receive various settings related to length measurement of the pattern from the user. When a mouse click operation or the like is performed on these buttons, the information processing device 1 displays a setting screen for receiving detailed settings on the display 14. The pre-processing setting button 302 is a button for setting pre-processing for adjusting brightness, contrast, or the like with respect to an SEM image. The automatic/manual setting button 303 is a button for setting whether the contour detection processing for length measurement is performed automatically or manually by the user. The information processing device 1 performs contour detection using a set of the similar image region and the mask image stored in the database described in the second embodiment when automatic is set by the user, and performs contour detection based on a prompt input by the user described in the first embodiment when manual is set. The segmentation setting button 304 is a button for setting a type, size, or the like of the training model used for the contour detection processing. When a mouse click operation or the like is performed on the length measurement start button 305 provided in the initial screen, the information processing device 1 starts length measurement processing for one or more SEM images displayed in the image display region 301.

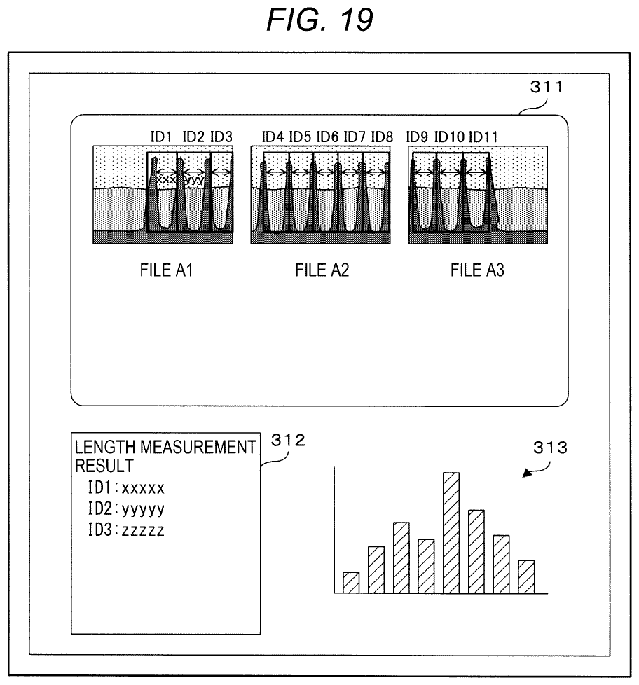

When the length measurement processing is started with the setting of automatically performing the length measurement, the information processing device 1 performs the pattern detection processing on the given one or more SEM images, acquires an image region and a mask image similar to the image region of the detected pattern from the database, and performs the contour detection processing. Further, the information processing device 1 performs the length measurement location detection processing based on a result of the contour detection, measures a length of the detected length measurement location, and displays a length measurement result on, for example, a length measurement result display screen illustrated in FIG. 19. In the length measurement result display screen displayed by the information processing device 1, for example, an image display region 311 for displaying a list of SEM images is provided in an upper portion of the screen, a numerical value display region 312 for displaying a list of numerical values of the length measurement result is provided at a left side of a lower portion of the screen, and a graph display region 313 for displaying a graph of the length measurement result is provided at a lower right part of the lower portion of the screen.

The SEM image displayed in the image display region 311 of the length measurement result display screen by the information processing device 1 is the same as the SEM image displayed in the image display region 301 of the initial screen. For each SEM image, the information processing device 1 displays one or more rectangular frames surrounding the image regions of the detected pattern, a two-way arrow indicating a length measurement location for each pattern, and identification information assigned to each pattern by the information processing device 1 in a superimposed manner. The information processing device 1 may display the mask image obtained as a contour detection result in the contour detection processing by, for example, color-coding the mask image for each pattern and superimposing the mask image on the SEM image.

The information processing device 1 displays, in the numerical value display region 312 of the length measurement result display screen, a list in which identification information attached to each pattern as a length measurement result and a numerical value of the length measurement result of the pattern are associated with each other, side by side in a vertical direction. The information processing device 1 displays, for example, a graph of a histogram that summarizes length measurement results of a plurality of patterns in the graph display region 313 of the length measurement result display screen. The histogram is a graph in which, for example, a horizontal axis represents a plurality of classes obtained by dividing numerical values (lengths) of length measurement results into appropriate ranges, and a vertical axis represents a number (frequency) of patterns corresponding to each class.

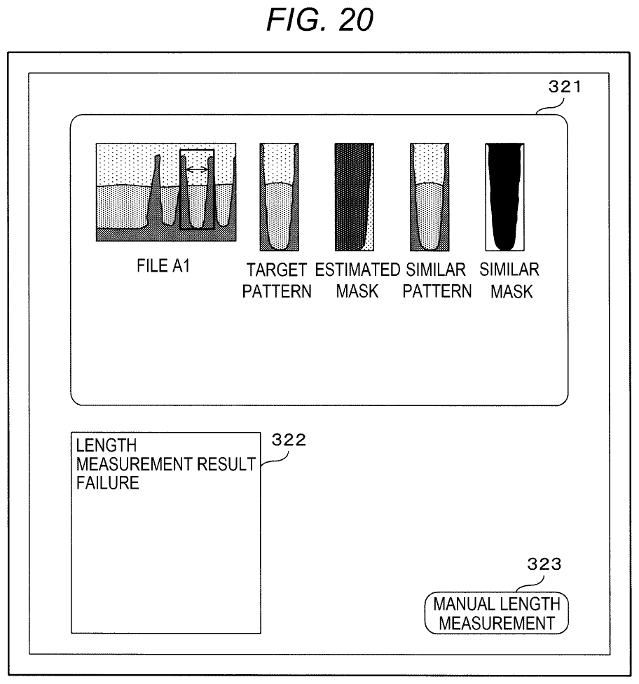

The length measurement result display screen illustrated in FIG. 19 is a screen when the information processing device 1 obtains a correct detection result by the contour detection processing. As illustrated in steps S76 to S79 of the flowchart in FIG. 16, when a correct contour detection result is not obtained based on the information stored in the database, the information processing device 1 performs contour detection based on an input from the user. When a correct detection result is not obtained by the contour detection processing, the information processing device 1 displays a failure notification screen illustrated in FIG. 20 on the display 14 to notify the user of a failure of automatic contour detection processing. In the failure notification screen displayed by the information processing device 1, for example, an image display region 321 for displaying an SEM image, a mask image, and the like related to a failed pattern is provided in an upper portion of the screen, a message display region 322 for notifying the user of a failure of a length measurement result is provided at a left side of a lower portion of the screen, and a manual length measurement button 323 for manually performing length measurement is provided at a lower right part of the lower portion of the screen.

The information processing device 1 displays, in the image display region 321 of the failure notification screen, an SEM image in which a pattern for which the contour detection processing has failed is captured, an image region (target pattern) of the pattern, a mask image (estimated mask) as a contour detection result performed for the image region, and an image region (similar pattern) and a mask image (similar mask) acquired from the database as being similar to the image region side by side. The estimated mask displayed here is an incorrect contour detection result obtained by the contour detection processing.

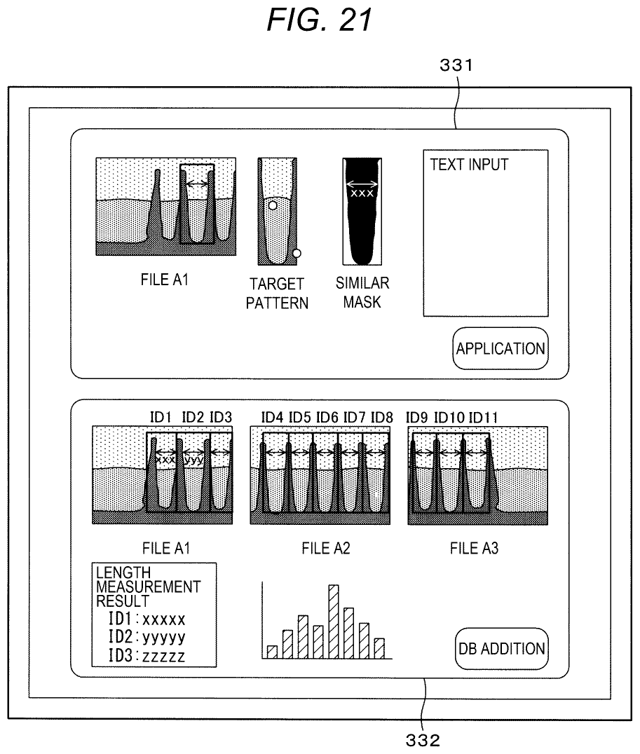

The information processing device 1 displays a message of “failure” as a length measurement result in the message display region 322 of the failure notification screen, thereby notifying the user that the automatic length measurement processing has failed. When a click operation or the like is performed on the manual length measurement button 323 provided on the failure notification screen, the information processing device 1 displays a manual length measurement screen illustrated in FIG. 21 on the display 14.

The manual length measurement screen displayed by the information processing device 1 is divided into two regions, for example, an upper region and a lower region, and the upper region is a prompt input region 331 for inputting information (prompt) such as a length measurement condition or setting, and the lower region is a length measurement result display region 332 for displaying a length measurement result.

The information processing device 1 displays, for example, an SEM image that is a length measurement target, at a left end of the prompt input region 331 of the manual length measurement screen, and receives an input of a rectangular frame surrounding a length measurement target pattern, an input of a start point and an end point of a length measurement location, or the like, based on a mouse operation or the like by the user. The information processing device 1 displays an image region (target pattern) of the length measurement target pattern extracted from the SEM image at a right side of the SEM image, and receives an input of a point in the pattern or a point not in the pattern for the image region from the user. The information processing device 1 uses these pieces of information input by the user as a prompt to perform contour detection using the contour detection model 200, and displays a mask image (estimated mask) obtained as a result of the contour detection at a right side of the target pattern. The information processing device 1 can receive an input of a prompt by inputting text in a natural language instead of or in addition to inputting a rectangular frame or point (coordinates), and a text box for inputting text is provided at a right end of the prompt input region 331. An application button is provided below the text box in the prompt input region 331, and when a click operation or the like is performed on the application button by the user, the information processing device 1 performs contour detection processing, length measurement location detection processing, length measurement processing, or the like for an identical pattern in one or more SEM images, by applying the condition input into the prompt input region 331.

The information processing device 1 displays one or more SEM images that are length measurement targets side by side in an upper portion of the length measurement result display region 332 of the manual length measurement screen, displays a list of length measurement results in a lower portion, and displays the length measurement result in a graph such as a histogram. Since information displayed in the length measurement result display region 332 is substantially the same as the information displayed on the length measurement result display screen in FIG. 19, a detailed description thereof will be omitted.

A DB addition button is provided in a lower right portion of the length measurement result display region 332 of the manual length measurement screen. When a click operation or the like is performed on the DB addition button, the information processing device 1 stores, in the database, a set of the target pattern and the estimated mask displayed in the prompt input region 331. At this time, the information processing device 1 may convert the target pattern into a feature, and store the feature in the database together with the target pattern and the estimated mask. These pieces of information stored in the database are used as search targets of similar patterns in the subsequent length measurement processing.

### <Summary>

In the information processing system according to the second embodiment configured as described above, the information processing device 1 stores a set of an image regions of a pattern and a mask image as a contour detection result thereof in the database. The information processing device 1 acquires the set of the image region and the mask image from the database based on the image region of the pattern detected from the SEM image, and detects a contour of the pattern from the image region detected from the SEM image based on the acquired set of the image region and the mask image. Accordingly, the information processing system according to the second embodiment can perform contour detection using the information stored in the database without receiving an input of condition information (prompt) for contour detection from the user.

In the information processing system according to the second embodiment, the information processing device 1 acquires a prompt when contour detection cannot be correctly performed based on the information stored in the database, detects a contour of the pattern from the image region based on the acquired prompt, and stores a set of the image region and the mask image as a contour detection result in the database. Accordingly, the information processing system according to the second embodiment can acquire a prompt from the user and perform contour detection when the contour detection cannot be correctly performed based on the information stored in the database, and can store a result of the contour detection in the database and use the result for the subsequent contour detection.

In the information processing system according to the second embodiment, the information processing device 1 acquires a set of the image region and the mask image from the database based on similarity between the image region that is a target for contour detection and the image region stored in the database. When no image region with similarity exceeding a threshold value is stored in the database, the information processing device 1 determines that a contour cannot be detected from the target image region, and acquires a prompt. Accordingly, the information processing system according to the second embodiment can be expected to acquire a set of the image regions and the mask images useful for contour detection from the database with respect to an image region that is a target for the contour detection.

In the information processing system according to the second embodiment, the information processing device 1 determines whether a correct contour can be detected from the image region based on similarity between the mask image as the contour detection result from the target image region and the mask image acquired from the database. Accordingly, the information processing system according to the second embodiment can be expected to accurately determine whether contour detection is possible based on information stored in the database.

In the information processing system according to the second embodiment, the information processing device 1 displays one or more SEM images on the display 14, and displays an image region of a pattern detected from the SEM image, a mask image as a contour detection result from the image region, or a length measurement location detected based on a link in a superimposed manner on the SEM image, and displays a length measurement result based on the length measurement location. By displaying these pieces of information, the information processing system according to the second embodiment can be expected to provide the user with detailed information on length measurement of the pattern.

In the information processing system according to the second embodiment, the information processing device 1 displays a histogram of length measurement results regarding a plurality of patterns detected from the SEM images. Accordingly, the information processing system according to the second embodiment can be expected to provide the user with information on variations in a shape of a pattern or the like.

In the information processing system according to the second embodiment, when a correct contour detection result is not obtained from the SEM image, the information processing device 1 displays, on the display 14, an original SEM image, an image region of a pattern, a mask image as an erroneous contour detection result obtained for this image region, and a set of the image region and the mask image acquired from the information stored in the database. The information processing device 1 receives an input of a prompt for the displayed SEM image. Accordingly, when a correct contour detection result is not obtained, the information processing system according to the second embodiment provides the user with information for determining a cause or the like thereof, and is expected to receive an input of a prompt based on the information.

The screen display by the information processing device 1 illustrated in FIGS. 18 to 21 in the second embodiment is an example and is not limited thereto. The information processing device 1 may display information on the pattern detection processing, the contour detection processing, the length measurement location detection processing, the length measurement processing, and the like on the display 14 in any form.

According to the present disclosure, it can be expected to support the detection processing related to a given pattern formed on the substrate.

Since the other configurations of the information processing system according to the second embodiment are similar as those of the information processing system according to the first embodiment, the same reference numerals are given to similar locations, and a detailed description thereof will be omitted.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

### Appendix

### (Appendix 1)

A computer program for causing a computer to perform detection processing, related to a plurality of patterns having a given shape formed on a substrate processed by a substrate processing device, on at least one captured image obtained by imaging the substrate, in which
the computer program causes the computer to:
   execute processing of
      detecting an image region in which one of the patterns is captured from the captured image,
      detecting a contour of the pattern in the image region, and
      detecting a length measurement location for the pattern based on a detection result of the contour,
   acquire condition information including at least one of coordinate designation, region designation, or text as a detection condition in at least one type of detection processing of the detection processing of the image region, the detection processing of the contour, and the detection processing of the length measurement location, and
   perform the detection processing related to another pattern based on the acquired condition information related to the one pattern.

### (Appendix 2)

The computer program according to Appendix 1, in which
a plurality of sets of the image region in which the pattern is captured and the detection result of the contour of the pattern in the image region are stored in a storage,
a set of the image region and the detection result of the contour is acquired from the storage based on the image region detected from the captured image, and
the contour of the pattern is detected from the image region detected from the captured image, based on the acquired set of the image region and the detection result of the contour.

### (Appendix 3)

The computer program according to Appendix 2, in which
the condition information is acquired when the contour of the pattern is not detectable from the image region,
the contour of the pattern is detected from the image region based on the acquired condition information, and
a set of the image region and the detection result of the contour is stored in the storage.

### (Appendix 4)

The computer program according to Appendix 2, in which
a set of the image region and the detection result of the contour is acquired from the storage based on similarity between the image region that is a detection target of the contour and each image region stored in the storage, and
when an image region in which the similarity exceeds a threshold value is not stored in the storage, a determination is made that the contour is not detectable from the image region.

### (Appendix 5)

The computer program according to Appendix 2, in which
a determination is made as to whether a correct contour of the pattern is detectable from the image region, based on similarity between the detection result of the contour from the image region of the pattern detected from the captured image and the detection result of the contour acquired from the storage.

### (Appendix 6)

The computer program according to Appendix 2, in which
a captured image of one or more processing targets is displayed,
the image region of the pattern detected from the captured image, the contour of the pattern detected from the image region, or the length measurement location detected based on the contour is displayed in a superimposed manner on the captured image, and a length measurement result based on the length measurement location is displayed.

### (Appendix 7)

The computer program according to Appendix 6, in which
a histogram of the length measurement results related to a plurality of patterns detected from the captured image is displayed.
   (appendix 8)

The computer program according to Appendix 3, in which
when a correct contour is not detectable from the image region, an original captured image in which the image region is detected, the image region, an erroneous contour detection result related to the image region, and a set of the image region and mask information acquired from the storage based on the image region are displayed.

### (Appendix 9)

The computer program according to Appendix 8, in which
an input of the condition information for the displayed captured image is received.

1. A non-transitory computer-readable medium storing executable instructions, which when executed by controller circuitry, cause the controller circuitry to perform a method of detection processing, related to a plurality of patterns having a given shape formed on a substrate processed by a substrate processing device, on at least one captured image obtained by imaging the substrate, the method of detection processing comprising:
detecting an image region in which one of the patterns is captured from the captured image;
detecting a contour of the pattern in the image region;
detecting a length measurement location for the pattern based on a detection result of the contour;
acquiring condition information including at least one of coordinate designation, region designation, or text as a detection condition in at least one type of detection processing of detection processing of the image region, the detection processing of the contour, and the detection processing of the length measurement location; and
performing the detection processing related to another pattern based on the acquired condition information related to the one pattern.

2. A non-transitory computer-readable medium storing executable instructions, which when executed by controller circuitry, cause the controller circuitry to perform a method of detection processing, related to a plurality of patterns having a given shape formed on a substrate processed by a substrate processing device, on at least one captured image obtained by imaging the substrate, the method of detection processing comprising:
acquiring an image region in which one of the patterns extracted from the captured image is captured;
acquiring condition information for detection including at least one of coordinate designation, region designation, or text;
detecting a contour of the pattern in the image region based on the condition information; and
performing the detection processing related to another pattern based on the acquired condition information related to the one pattern.

3. The non-transitory computer-readable medium according to claim 1, the method of detection processing further comprising:
detecting the contour of the pattern in one image region by inputting the one image region and the acquired condition information to a trained first segmentation model that receives an image and the condition information as inputs and classifying a plurality of pixels configuring the image based on the condition information, and acquiring a segmentation result obtained by the first segmentation model; and
detecting a contour of the pattern in another image region by inputting the one image region, a segmentation result of the one image region, and the other image region into a trained second segmentation model that receives a reference image, a segmentation result of the reference image, and a target image as inputs and performing segmentation of the target image, and acquiring a segmentation result obtained by the second segmentation model.

4. The non-transitory computer-readable medium according to claim 1, the method of detection processing further comprising:
generating condition information for the detection processing related to the other pattern based on the acquired condition information related to the one pattern.

5. The non-transitory computer-readable medium according to claim 4, the method of detection processing further comprising:
detecting the contour of the pattern in one image region by inputting the one image region and the acquired condition information to a trained segmentation model that receives an image and the condition information as inputs and classifying a plurality of pixels configuring the image based on the condition information, and acquiring a segmentation result obtained by the segmentation model;
calculating a feature of each pixels of the one image region and the other image region;
extracting similar pixels of the one image region and the other image region based on the calculated feature; and
generating condition information for segmentation related to the other image region based on the segmentation result related to the one image region and the extracted similar pixels.

6. The non-transitory computer-readable medium according to claim 1, wherein
the condition information includes information designating a pixel in a detection target pattern or information designating a pixel not in the pattern.

7. The non-transitory computer-readable medium according to claim 1, the method of detection processing further comprising:
outputting a detection result of the contour of the pattern;
receiving an input of correction information for the detection result; and
correcting the detection result based on the correction information.

8. The non-transitory computer-readable medium according to claim 7, the method of detection processing further comprising:
receiving an input of correction information for the detection result related to the one pattern; and
correcting the detection result related to the other pattern based on the correction information.

9. The non-transitory computer-readable medium according to claim 2, the method of detection processing further comprising:
acquiring condition information for detecting a length measurement location that includes at least one of the coordinate designation, the region designation, or the text;
detecting the length measurement location for the pattern based on the detection result of the contour and the condition information; and
performing the detection processing related to the other pattern based on the acquired condition information related to the one pattern.

10. A non-transitory computer-readable medium storing executable instructions, which when executed by controller circuitry, cause the controller circuitry to perform a method of detection processing, related to a plurality of patterns having a given shape formed on a substrate processed by a substrate processing device, on at least one captured image obtained by imaging the substrate, the method of detection processing comprising:
acquiring a detection result of a contour of one of the patterns in an image region in which the pattern is captured;
acquiring condition information for detection including at least one of coordinate designation, region designation, or text;
detecting a length measurement location for the pattern based on the detection result of the contour and the condition information; and
performing the detection processing related to another pattern based on the acquired condition information related to the one pattern.

11. The non-transitory computer-readable medium according to claim 1, the method of detection processing further comprising:
detecting the length measurement location for the one pattern by inputting the detection result of the contour of the one pattern and the condition information to a trained first length measurement location detection model that receives the detection result of the contour and the condition information as inputs and outputting information on the length measurement location for the pattern, and acquiring the information on the length measurement location output by the first length measurement location detection model; and
detecting the length measurement location for the other pattern by inputting the detection result of the contour of the one pattern, a detection result of the length measurement location of the one pattern, and the detection result of the contour of the other pattern to a trained second length measurement location detection model that receives a reference image, a detection result of the length measurement location of the reference image, and a target image as inputs and outputting information on the length measurement location of the target image, and acquiring the information on the length measurement location output by the second length measurement location detection model.

12. The non-transitory computer-readable medium according to claim 1, the method of detection processing further comprising:
determining a state of the pattern is based on a result of the detection processing.

13. The non-transitory computer-readable medium according to claim 1, the method of detection processing further comprising:
measuring a length of the pattern based on a detection result of the length measurement location; and
determining a state of the pattern based on a length measurement result.

14. The non-transitory computer-readable medium according to claim 1, the method of detection processing further comprising:
storing the condition information in a storage; and
acquiring the condition information used for the detection processing from the storage.

15. The non-transitory computer-readable medium according to claim 1, the method of detection processing further comprising:
storing, in a storage, a plurality of sets of the image region in which the pattern is captured and the detection result of the contour of the pattern in the image region;
acquiring, from the storage, a set of the image region and the detection result of the contour based on the image region detected from the captured image; and
detecting the contour of the pattern from the image region detected from the captured image, based on the acquired set of the image region and the detection result of the contour.

16. The non-transitory computer-readable medium according to claim 15, the method of detection processing further comprising:
acquiring the condition information when the contour of the pattern is not detectable from the image region;
detecting the contour of the pattern from the image region based on the acquired condition information; and
storing, in the storage, the set of the image region and the detection result of the contour.

17. The non-transitory computer-readable medium according to claim 15, the method of detection processing further comprising:
acquiring, from the storage, the set of the image region and the detection result of the contour based on similarity between the image region that is a detection target of the contour and each image region stored in the storage; and
when an image region in which the similarity exceeds a threshold value is not stored in the storage, determining that the contour is not detectable from the image region.

18. The non-transitory computer-readable medium according to claim 15, the method of detection processing further comprising:
determining as to whether the contour of the pattern is detectable from the image region, based on similarity between the detection result of the contour from the image region of the pattern detected from the captured image and the detection result of the contour acquired from the storage.

19. An information processing method in which an information processing device performs detection processing, related to a plurality of patterns having a given shape formed on a substrate processed by a substrate processing device, on at least one captured image obtained by imaging the substrate, the information processing method comprising:
detecting an image region in which one of the patterns is captured from the captured image;
detecting a contour of the pattern in the image region;
detecting a length measurement location for the pattern based on a detection result of the contour;
acquiring condition information including at least one of coordinate designation, region designation, or text as a detection condition in at least one type of detection processing of detection processing of the image region, the detection processing of the contour, and the detection processing of the length measurement location; and
performing the detection processing related to another pattern based on the acquired condition information related to the one pattern.

20. An information processing device comprising:
controller circuitry configured to perform detection processing, related to a plurality of patterns having a given shape formed on a substrate processed by a substrate processing device, on at least one captured image obtained by imaging the substrate, wherein the controller circuitry is further configured to detect an image region in which one of the patterns is captured from the captured image;
detect a contour of the pattern in the image region;
detect a length measurement location for the pattern based on a detection result of the contour;
acquire condition information including at least one of coordinate designation, region designation, or text as a detection condition in at least one type of detection processing of detection processing of the image region, the detection processing of the contour, and the detection processing of the length measurement location; and
perform the detection processing related to another pattern based on the acquired condition information related to the one pattern.
